(19) United States
(12) Patent Application Publication
(10) Pub. No.: US 2026/0282894 A1
(43) Pub. Date: Sep. 17, 2026

(54) SEMICONDUCTOR PACKAGE STRUCTURE AND METHOD OF FORMING THE SAME

(71) Applicant: TAIWAN SEMICONDUCTOR MANUFACTURING COMPANY LTD., HSINCHU (TW)

(72) Inventors: HARRY-HAKLAY CHUANG, HSINCHU COUNTY (TW); CHIH-REN HSIEH, CHANGHUA COUNTY (TW); WEI-CHENG WU, HSINCHU COUNTY (TW); LI-FENG TENG, HSINCHU CITY (TW); KUEN-YI CHEN, HSINCHU CITY (TW); YI CHING ONG, HSINCHU (TW); KUO-CHING HUANG, HSINCHU CITY (TW)

(21) Appl. No.: 19/278,843

(22) Filed: Jul. 24, 2025

Related U.S. Application Data
(60) Provisional application No. 63/769,795, filed on Mar. 11, 2025.

(51) Int. Cl. H01L 23/522; H01L 21/768; H01L 23/00; H01L 23/48

(52) U.S. Cl. CPC H10W 20/496; H10W 20/01; H10W 20/20; H10W 80/312; H10W 80/327; H10W 90/792

(57) ABSTRACT

A method includes: forming a first device region including a first semiconductor substrate; forming a first interconnect structure over a first front side of the first semiconductor substrate, wherein the first device region and the first interconnect structure form a first semiconductor die; forming a second device region including a second semiconductor substrate; forming a second interconnect structure over a second front side of the second semiconductor substrate, wherein the second device region and the second interconnect structure form a second semiconductor die; flipping the second semiconductor die and bonding the first semiconductor die with the second semiconductor die at a bonding region between the first interconnect structure and the second interconnect structure; and forming a third interconnect structure on a backside of the first semiconductor substrate, wherein the of the third interconnect structure includes a capacitor between two adjacent metallization layers of the third interconnect structure.

### PRIORITY CLAIM AND CROSS-REFERENCE

The present application claims the benefit of prior-filed U.S. provisional Application No. 63/769,795, filed on Mar. 11, 2025, the content of which is hereby incorporated by reference in its entirety.

### BACKGROUND

The semiconductor industry continues to improve the integration density of various electronic components (e.g., capacitors) while the minimum feature size is continually reduced, which allow more components to be integrated into a given area. These smaller electronic components also require smaller packages that utilize less area than packages of the previous generations.

One type of capacitor is a metal-insulator-metal (MIM) capacitor. The MIM capacitors may be used as decoupling capacitors. An MIM capacitor is formed horizontally on a semiconductor wafer, with two or more metal plates sandwiching an insulating layer parallel to the wafer surface. However, the formation of the MIM capacitors are facing challenges in different package structure constraints.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic diagram of a semiconductor processing system, in accordance with some embodiments of the present disclosure.

FIG. 2A is a cross-sectional view of a semiconductor die package, in accordance with some embodiments of the present disclosure.

FIG. 2B is an enlarged view of a region of the semiconductor die package shown in FIG. 2A, in accordance with some embodiments of the present disclosure.

FIG. 2C is an enlarged view of a region of the semiconductor die package shown in FIG. 2A, in accordance with some embodiments of the present disclosure.

FIG. 2D is an enlarged view of a region of the semiconductor die package shown in FIG. 2A, in accordance with some embodiments of the present disclosure.

FIG. 2E is a cross-sectional view of a semiconductor die package, in accordance with some embodiments of the present disclosure.

FIG. 3A is a cross-sectional view of a semiconductor die package, in accordance with some embodiments of the present disclosure.

FIG. 3B is an enlarged view of a region of the semiconductor die package shown in FIG. 3A, in accordance with some embodiments of the present disclosure.

FIG. 4A is a cross-sectional view of a semiconductor die package, in accordance with some embodiments of the present disclosure.

FIG. 4B is a perspective view of a region of the semiconductor die package shown in FIG. 4A, in accordance with some embodiments of the present disclosure.

FIG. 4C is a perspective view of a region of the semiconductor die package shown in FIG. 4A, in accordance with some embodiments of the present disclosure.

FIG. 4D is a cross-sectional view of a semiconductor die package, in accordance with some embodiments of the present disclosure.

FIG. 5 is a cross-sectional view of a semiconductor die package, in accordance with some embodiments of the present disclosure.

FIGS. 6A to 6G are schematic cross-sectional views of intermediate stages of a method of forming a semiconductor die, in accordance with some embodiments of the present disclosure.

FIGS. 7A to 7F are schematic cross-sectional views of intermediate stages of a method of forming a capacitor, in accordance with some embodiments of the present disclosure.

FIGS. 8A to 8D are schematic cross-sectional views of intermediate stages of a method of forming a semiconductor die, in accordance with some embodiments of the present disclosure.

FIGS. 9A to 9H are schematic cross-sectional views of intermediate stages of a method of forming a semiconductor die package, in accordance with some embodiments of the present disclosure.

FIG. 10 shows a flowchart of a method of manufacturing a semiconductor die package, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “substantial” or “substantially” generally mean within 10%, 5%, 1% or 0.5% of a given value or range. Alternatively, the terms “about,” “substantial” or “substantially” mean within an acceptable standard error of the mean when considered by one of ordinary skill in the art. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “about,” “substantial” or “substantially.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

Embodiments of the present disclosure generally discuss decoupling capacitors, e.g., MIM (metal-insulator-metal) capacitors, and semiconductor die packages including the decoupling capacitors, in particular discuss decoupling capacitors and hybrid-bonded semiconductor die packages including the decoupling capacitors. In some suitable methods of semiconductor die packages, e.g., using micro-bump bonding, the decoupling capacitors are formed immediately adjacent the layers of conductive pads, e.g., aluminum connector pads, or near the top layers of metallization layers of the interconnect structure, in order to secure a sufficiently large area of electrode plates of the decoupling capacitors, thereby achieving large capacitance of the decoupling capacitors. However, as the bonding technology evolves, the layers of aluminum connector pads may be replaced with dielectric/copper bonding layers of hybrid bonding. The original processes and recipes for forming the decoupling capacitors in micro-bump bonding may not be applicable for the structure of hybrid-bonded die package.

Several configurations of the MIM capacitor are proposed in the present disclosure to fill the gap of the decoupling capacitor formation in the hybrid-bonded die package structures. According to some embodiments, the MIM capacitors are formed on a backside of one or more component semiconductor dies of the semiconductor die package, and electrically connected to the device region in the front side of the of the component dies through a backside through-silicon via (BTSV). According to some other embodiments, the MIM capacitors are additionally or alternatively formed in a metallization layer near the bonding region of the hybrid bond on a front side of one or more component semiconductor dies of the semiconductor die package, and electrically connected to the device region of the components of the semiconductor die package through the front-side interconnect structure and/or backside interconnect structure of the respective component semiconductor dies. The MIM capacitors can therefore be compatible with the advanced semiconductor die package with hybrid bonding, and the utilization efficiency of the MIM capacitor areas can be maximized.

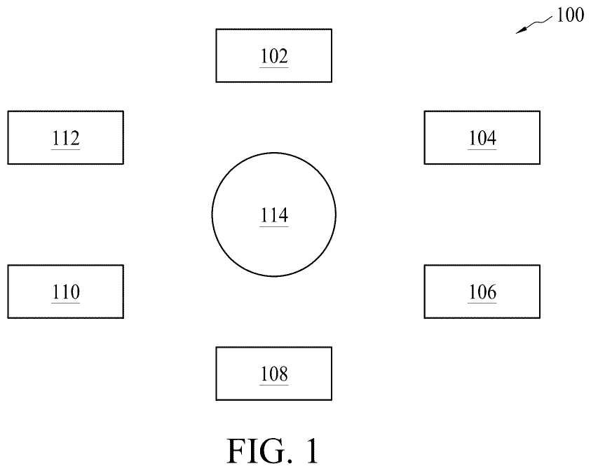

FIG. 1 is a schematic diagram of a semiconductor processing system 10, in accordance with some embodiments of the present disclosure. The semiconductor processing system 10 may be used to process a semiconductor wafer or substrate to thereby fabricate a semiconductor chip, a semiconductor die, semiconductor structure, a semiconductor package, or the like. The semiconductor processing system 10 may include a deposition tool 102, an exposure tool 104, a developer tool 106, an etch tool 108, a planarization tool 110, a bonding tool 112 and a transport tool 114. According to some embodiments, more tools may be incorporated into the semiconductor processing system 10. According to some other embodiments, some of the aforementioned tools are omitted from the semiconductor processing system 10. The semiconductor processing system 10 may be arranged in a semiconductor clean room or other types of semiconductor processing facility with facility equipment to control environmental factors, such as a predetermined temperature, a predetermined humidity, a predetermined air quality, a predetermined quake-proof capability, and the like.

According to some embodiments, the deposition tool 102 is a semiconductor processing tool that includes a semiconductor processing chamber and configured to deposit various types of materials onto a substrate or a device layer. According to some embodiments, the deposition tool 102 is configured to perform chemical vapor deposition (CVD), e.g., plasma-enhanced CVD (PECVD), metal-organic CVD (MOCVD), high-density plasma CVD (HDP-CVD), sub-atmospheric CVD (SACVD), low-pressure CVD (LPCVD), photo-initiated CVD, atomic layer deposition (ALD), thermal ALD, plasma-enhanced ALD (PEALD), or another type of CVD.

According to some embodiments, the deposition tool 102 is configured to perform physical vapor deposition (PVD), such as sputtering, vacuum deposition, or another type of PVD. According to some embodiments, the deposition tool 102 is configured to perform epitaxial growth, such as solid-phase, liquid-phase, vapor-phase, and molecular-beam deposition, vapor-phase epitaxy (VPE), or another type of epitaxial growth.

According to some embodiments, the exposure tool 104 is a semiconductor processing tool configured to expose a photosensitive layer, e.g., photoresist, to a radiation source, such as an ultraviolet (UV) light source (e.g., deep UV (DUV), extreme UV (EUV), or the like), an X-ray source, an electron beam (e-beam) source, and/or the like. The light beam of the radiation source is patterned by being transmitted through a patterned photomask, and portions of the photosensitive layer exposed to the patterned radiation source may react to the energy of the radiation source, and thus the pattern of the photomask is optically transferred to the photosensitive layer. The patterned photosensitive layer after development may be used as a mask layer for a subsequent etching or deposition operation. According to some embodiments, the exposure tool 104 includes a scanner, a stepper, exposure lenses, or the like.

The developer tool 106 is a semiconductor processing tool configured to develop a photosensitive layer that has been exposed to a patterned radiation source by the exposure tool 104. According to some embodiments, the developer tool 106 develops a pattern by dissolving unwanted portions of the photosensitive layer. The developer dissolves either the exposed portions or the unexposed portions of the photosensitive layer depending on the optical property of the photosensitive layer. After development, the patterned photosensitive layer allows for deposition of a material in the exposed portions of the photosensitive layer, or allows to etching of a layer underlying the photosensitive layer through the exposed portions.

According to some embodiments, the etch tool 108 is a semiconductor processing tool configured to perform an etching operation on a substrate or a layer. The etch tool 108 may perform a wet etch, a dry etch, a combination thereof, e.g., a reactive ion etch (RIE), or the like. According to some embodiments, a gaseous or liquid etching chemical is used as an etchant to aid in the etching operation. According to some embodiments, the etch efficiency is enhanced through introduction of a plasma.

The planarization tool 110 is a semiconductor processing tool configured to perform a planarization operation to polish or planarize a surface of a substrate or a wafer. The planarization operation can remove excess materials of a layer and level upper surfaces of different layers of a semiconductor structure or semiconductor device. The planarization tool 110 may include a chemical mechanical planarization (CMP) tool, a mechanical grinding tool, a laser etch tool, and/or another type of planarization tool. During operation of CMP, a polishing head with abrasives is used to engage a surface of a layer to be planarized and presses against the surface with a grinding operation to remove the material with a predetermined removal rate. According to some embodiments, an abrasive and corrosive chemical slurry may be utilized to aid in the planarization performance during the grinding operation.

According to some embodiments, the bonding tool 112 is a semiconductor processing tool configured to perform a bonding operation of two work pieces (e.g., two semiconductor substrates, semiconductor devices, or semiconductor dies) together. The bonding tool 12 is configured to perform thermal bonding, thermal compression bonding, eutectic bonding, micro-bump bonding, hybrid bonding, or the like. According to some embodiments, a hybrid bonding is performed at a bonding region at an interface between the bonding surfaces of the two work pieces, where each bonding surface of each of the two work pieces includes a metallic surface (e.g., a copper surface) and a dielectric surface (e.g., an oxide surface). During operation, the metallic surfaces of the two bonding surfaces are bonded together to form a metallic bonded structure, while the dielectric surfaces of the two bonding surfaces are bonded together to form a dielectric bonded structure.

According to some embodiments, the transport tool 114 is configured to move a work piece, e.g., a semiconductor die, a semiconductor wafer, or the like, between different semiconductor processing tools 102, 104, 106, 108, 110 and 112, configured to move a work piece between processing chambers within the semiconductor processing tool 102, 104, 106, 108, 110 and 112, or configured to transport a work piece to and from different tools or other locations such as a wafer rack, a storage room, and/or the like. According to some embodiments, the transport tool 114 includes one or more robot arms, a tram or rail car, an overhead hoist transport (OHT) system, an automated material handling system (AMHS), and/or another type of electrical/mechanical components. The transport tool 116 may be a programmed tool that is configured to operate according to a production schedule. In some embodiments, the semiconductor processing system 10 includes a plurality of the transport tools 114 that work collaboratively to transport a plurality of work pieces across different tool clusters at scheduled times.

The tools 102-114 may be employed to fabricate the semiconductor structures or semiconductor die packages described with reference to the following figures.

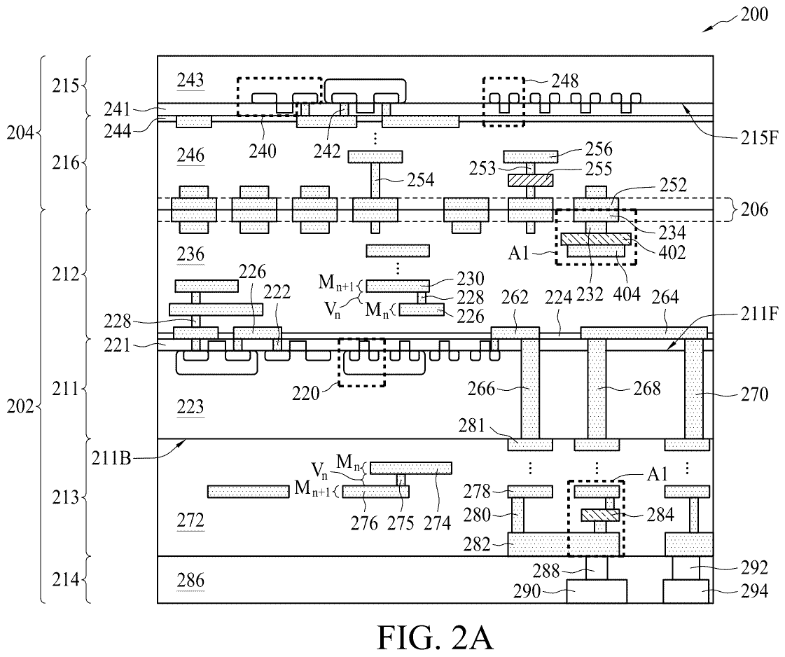

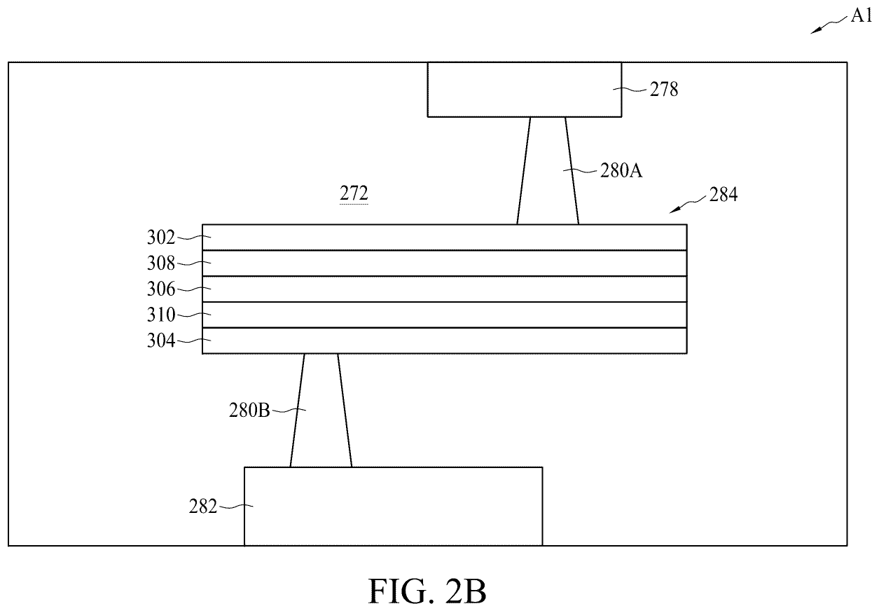

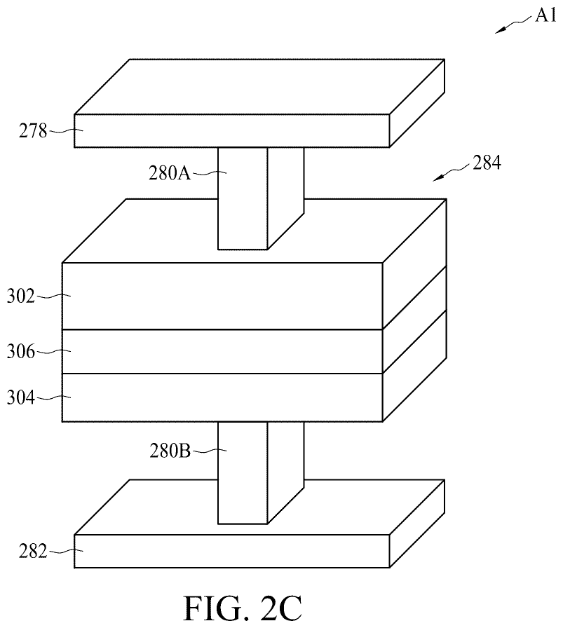

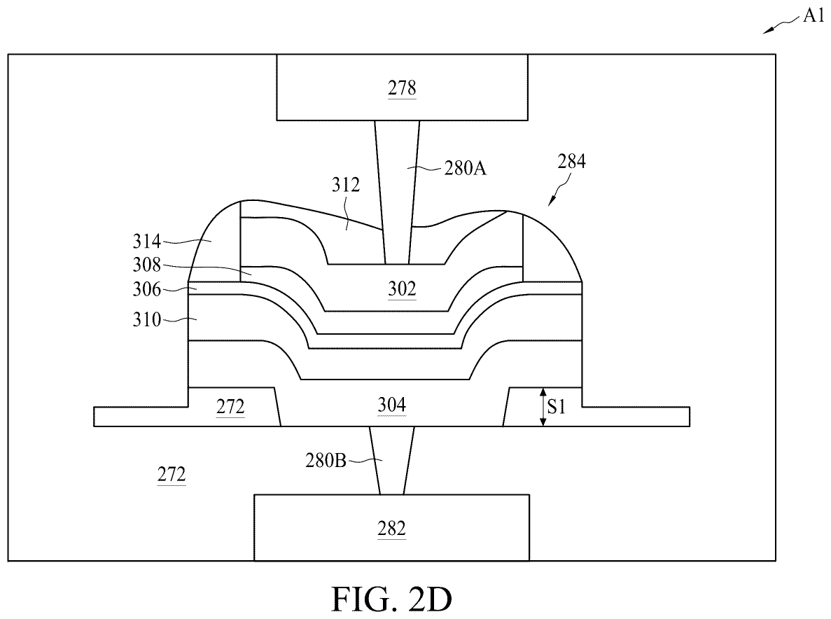

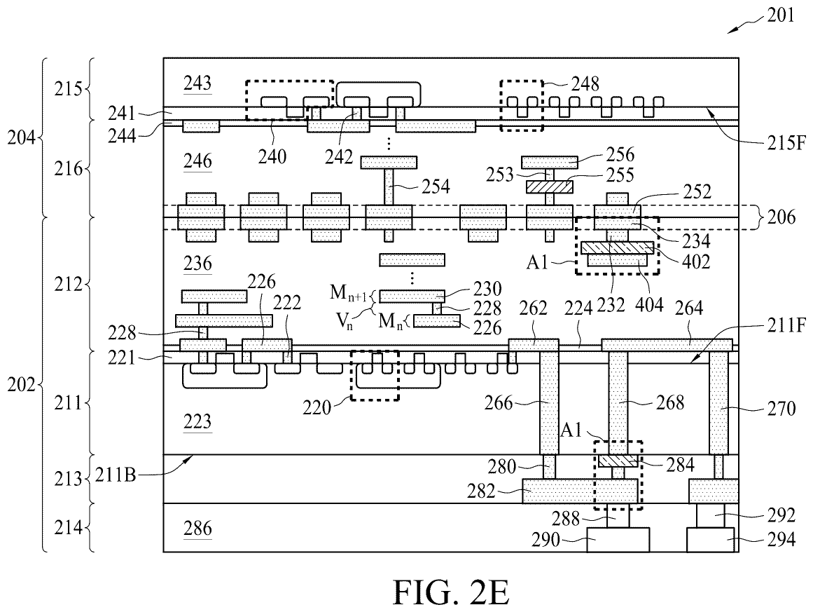

FIG. 2A is a cross-sectional view of a semiconductor die package 200, in accordance with some embodiments of the present disclosure. The semiconductor die package 200 may be a two-dimensional (2D) integrated circuit (IC), a 2.5DIC, a 3DIC, a chip on wafer on substrate (CoWoS) IC, or another suitable type of IC. According to some embodiments, the semiconductor die package 200 includes a first semiconductor die 202 and a second semiconductor die 204. The first semiconductor die 202 and the second semiconductor die 204 are bonded together, e.g., through hybrid bonding. According to some embodiments, the semiconductor die package 200 includes additional semiconductor dies.

According to some embodiments, the first semiconductor die 202 includes a logic semiconductor die, such as a system on chip (SoC) die, a central processing unit (CPU) die, a graphics processing unit (GPU) die, a microcontroller die, a digital signal processing (DSP) die, a network integrated circuit die, an application specific integrated circuit (ASIC) die, a field-programmable gate array (FPGA) die, a logic die, an integrated passive device (IPD) die, or the like. According to some embodiments, the second semiconductor die 204 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, or another type of die. The first semiconductor die 202 may be similar to the second semiconductor die 204.

According to some embodiments, the first semiconductor die 202 includes a device region 211, a front-side interconnect structure 212, a backside interconnect structure 213 and a redistribution layer (RDL) 214. According to some embodiments, more components may be incorporated into the first semiconductor die 202, or at least one of the aforementioned components is omitted from the first semiconductor die 202.

The device region 211 includes a semiconductor substrate 223. The semiconductor substrate 223 includes a semiconductor material such as silicon, and may include polysilicon. In some embodiments, the semiconductor substrate 223 includes other semiconductor materials, such as silicon germanium, silicon carbide, gallium arsenide, or the like. In some embodiments, the semiconductor substrate 223 is a p-type semiconductive substrate (acceptor type) or an n-type semiconductive substrate (donor type). Alternatively, the semiconductor substrate 223 includes another elementary semiconductor, such as germanium; a compound semiconductor including gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In yet another alternative, the semiconductor substrate 223 is a semiconductor-on-insulator (SOI) substrate. In some embodiments, the semiconductor substrate 223 includes a doped epitaxial layer, a gradient semiconductor layer, and/or a semiconductor layer overlaying another semiconductor layer of a different type, such as a silicon layer on a silicon germanium layer.

According to some embodiments, one or more semiconductor devices 220 are formed on the front surface or front side 211F of the semiconductor substrate 223 of the device region 211. The one or more semiconductor devices 220 may be referred to herein as logic devices, memory devices, peripheral devices, or another suitable type of device. In embodiments where the semiconductor devices 220 are logic devices, the one or more semiconductor devices 220 include metal-oxide-semiconductor field-effect transistors (MOSFETs), and can be planar FETs, fin-based FETs (FinFET), gate-all-around FETs (GAAFETs), nanowire FETs, nanosheet FETs, complementary FETs (CFETs), bipolar junction transistors (BJT), or another type of transistor. According to some embodiments, the semiconductor device 220 includes one or more well regions, a gate structure, a pair of source/drain doped regions, a channel region adjacent to the gate electrode and between the source/drain doped regions, and other doped regions. Further, the device region 211 may include a dielectric layer 221, sometimes also referred to as an inter-dielectric (ILD) layer, arranged over the front side 211F of the semiconductor substrate 223 and laterally surrounding the gate electrode of the semiconductor devices 220. The device region 211 may also include contacts 222 electrically connected to the source/drain doped regions and the gate electrodes of the semiconductor devices 220.

Throughout the present disclosure, a front side of a semiconductor substrate, for example, semiconductor substrate 223, or a device region, e.g., device region 211, is defined as a side or surface of the semiconductor substrate or the device region where active devices are formed. Moreover, throughout the present disclosure, a backside of a semiconductor substrate or a device region is defined as a side or surface of the semiconductor substrate or the device region opposite to the front side. According to some embodiments, the backside is free of any active devices. According to some embodiments, the backside is free of any passive devices or electrical circuits or, alternatively, the passive devices or electrical circuits are formed on the backside and electrically connected to the active devices on the front side.

The front-side interconnect structure 212 is formed over the front side 211F of the semiconductor substrate 223. According to some embodiments, the front-side interconnect structure 212 is formed of a plurality of metallization layers interconnected to construct conduction paths, wherein the conduction paths electrically interconnect the elements of the various semiconductor devices 220 in the device region 211, or electrically connect the semiconductor devices 220 with the overlying structures, e.g., the second semiconductor die 204. According to some embodiments, the metallization layers include metal line layers Mn each including respective conductive lines, e.g., 226, 230, and metal via layers Vn each including respective conductive vias, e.g., 228, where n signifies a layer index of the metal line layer Mn or the metal via layer Vn. Each of the metal line layers Mn includes a plurality of horizontally-extending conductive lines 226 or 230 (or wires, traces, strips, and the like), while each of the metal via layers Vn includes a plurality of vertically-extending conductive vias 228 (or posts, pillars, and the like). Two conductive lines 226 and 230 arranged in adjacent metal line layers Mn and M(n+1) may be electrically connected through a conductive via 228 in an intervening metal via layer Vn.

According to some embodiments, each metallization layers of the front-side interconnect structure 212 includes one or more insulating layers encapsulating and electrically insulating the conductive lines or conductive vias. The insulating layers may include one or more dielectric layers, collectively referred to as the dielectric layer 236, which may include silicon nitride, silicon oxide, silicon carbide, silicon oxynitride, low dielectric constant (low-k) dielectric materials, or another type of dielectric materials. According to some embodiments, one or more etch stop layers (ESLs) are included between the component layers of the dielectric layer 236. The one or more ESLs may include aluminum oxide, aluminum nitride, silicon nitride, silicon oxynitride, aluminum oxynitride, and the like. The ESLs may include a material different from that of the component layers of the dielectric layer 236. The ESLs may include an etch rate different from that of the component layers of the dielectric layer 236 with respect to a specific echant.

According to some embodiments, the conductive lines, e.g., 226 and 230, and the conductive vias, e.g., 228 are formed of conductive materials, e.g., metallic materials, such as copper (Cu), gold (Au), silver (Ag), nickel (Ni), tin (Sn), ruthenium (Ru), aluminum (Al), cobalt (Co), tungsten (W), titanium (Ti), and the like. According to some embodiments, the conductive lines 226, 230 or conductive vias 228 of the respective metallization layers include a multilayer structure, e.g., a seed layer and/or diffusion barrier layer may be formed between the conductive material and the surrounding dielectric layer 236 or the ESLs.

The backside interconnect structure 213 is formed over the backside 211B of the semiconductor substrate 223. According to some embodiments, the backside interconnect structure 213 is formed of one or more metallization layers interconnected to construct conduction paths, wherein the conduction paths electrically interconnect the elements of the various semiconductor devices 220 in the device region 211, or electrically connect the semiconductor devices 220 with the underlying structures, e.g., the RDL 214. According to some embodiments, the metallization layers include metal line layers Mn each including respective conductive lines, e.g., 274, 276, and metal via layers Vn each including respective conductive vias, e.g., 275, where n signifies a layer index of the metal line layer Mn or the metal via layer Vn. Each of the metal line layers Mn includes a plurality of horizontally-extending conductive lines 274 or 276 (or wires, traces, strips, and the like), while each of the metal via layers Vn includes a plurality of vertically-extending conductive vias 275 (or posts, pillars, and the like). Two conductive lines 274 and 276 arranged in adjacent metal line layers Mn and M(n+1) may be electrically connected through a conductive via 275 in an intervening metal via layer Vn.

According to some embodiments, each metallization layers of the backside interconnect structure 213 includes one or more insulating layers, collectively referred to as a dielectric layer 272, encapsulating and electrically insulating the conductive lines or conductive vias of the backside interconnect structure 213. The materials, configurations and method of forming for the dielectric layer 272 are similar to the dielectric layer 236, and details of these similar features are not repeated for brevity.

According to some embodiments, the materials, configurations and method of forming for the conductive lines, e.g., 274 and 276, and the conductive vias, e.g., 275 are similar to the conductive lines 226, 230 and the conductive via 228, respectively, and details of these similar features are not repeated for brevity.

According to some embodiments, the device region 211 includes one or more backside through-silicon vias (BTSVs), e.g., BTSVs 226, 268, 270, extending through the entire thickness of the substrate 223. The front-side interconnect structure 212 may include conductive lines 262 and 264 formed above the BTSVs 266, 258, 270, wherein the conductive line 262 electrically connects a semiconductor device 220 to the BTSV 266, and the conductive line 264 electrically connects the BTSV 268 to the BTSV 270. The backside interconnect structure 213 may include conductive lines 281 formed on the backside 211B and arranged in a top (or bottom) metal line layer M1 of the metallization layers of the backside interconnect structure 213, in which the conductive lines 281 are electrically connected to the BTSVs 266, 268 and 270. According to some embodiments, the BTSVs 266, 268 and 270 include a length substantially equal to or greater than the thickness of the substrate 223. The BTSVs 266, 268 and 270 may include a width greater than a width of the conductive via 228 in the front-side interconnect structure 212 or a width of the conductive via 275 in the backside interconnect structure 213.

According to some embodiments, the RDL 214 is arranged over a side of the backside interconnect structure 213 opposite to the device region 211. The RDL 214 serves as a connector layer of the semiconductor die package 200 and is configured to electrically connect the semiconductor die package 200 to an external circuit (not separately shown). The RDL 214 includes conductive vias 288 and 292 and conductive pads (connectors) 290 and 294 electrically connected to the conductive vias 288 and 292, respectively. According to some embodiments, the conductive pads 290 and 294 are electrically connected to a power terminal and a ground terminal, respectively, or vice versa, of an external power source. The conductive vias 288, 292 and the conductive pads 290, 294 may include a material different from that of the metal line layers and metal via layers in the front-side interconnect structure 212 or the backside interconnect structure 213. For example, the conductive lines 226, 230, 274, 276 or the conductive vias 228, 275 may be formed of copper, while the conductive vias 288, 292 and the conductive pads 290, 294 may be formed of aluminum or an alloy of aluminum, such as a copper-aluminum alloy.

According to some embodiments, the RDL 214 further includes a dielectric layer 386 electrically insulating the conductive vias 288 and 292 and conductive pads 290 and 294 in a manner similar to the dielectric layer 236 or 272. Although FIG. 2A only shows two conductive vias 288. 292 and two conductive pads 290 and 294, the RDL 214 can include more conductive vias and conductive pads in other embodiments, in which the additional conductive pads serve as signal terminals to transmit electrical signals for the first semiconductor die 202 or the second semiconductor die 204.

According to some embodiments, the second semiconductor die 204 includes a device region 215 and a front-side interconnect structure 216 formed on the front side 215F of the device region 215. The device region 215 includes a semiconductor substrate 243. The semiconductor substrate 243 may be similar to the semiconductor substrate 223. According to some embodiments, one or more semiconductor devices 240 are formed on the front side 215F of the semiconductor substrate 243. Further, the device region 215 may include an ILD layer 241 arranged over the front side 211F of the semiconductor substrate 243. The device region 215 may also include contacts 242 electrically connected to the source/drain doped regions and the gate electrodes of the semiconductor devices 240. The abovementioned components of the second semiconductor die 204 are similar to those of the first semiconductor die 202, and the details of these features are not repeated for brevity.

According to some embodiments, the device region 215 further includes one or more semiconductor devices 248 formed thereon. The semiconductor devices 240 and the semiconductor devices 248 may be different types of devises, e.g., the semiconductor devise 240 are active devices, such as transistors, while the semiconductor devices 248 are passive devices, such as trench-type capacitors, resistors, inductors, fuses, diodes, or the like.

Further, the front-side interconnect structure 216 includes a plurality of metallization layers that include metal line layers Mn and metal via layers Vn. Each of the metal line layers Mn may include a plurality of conductive lines 252, and each of the metal via layers Vn may include a plurality of conductive vias 254. The front-side interconnect structure 216 may further include dielectric layer 246 and one or more ESLs 244 encapsulating and electrically insulating the conductive lines 252 and the conductive vias 254 in each metal line layer or metal via layer. The aforementioned components of the front-side interconnect structure 216 are similar to those of the front-side interconnect structure 212, and details of these similar features are not repeated for brevity.

According to some embodiments, the front-side interconnect structure 212, the backside interconnect structure 213 or the front-side interconnect structure 216 includes one or more capacitor structures. For example, the front-side interconnect structure 212 includes a capacitor structure 402, the backside interconnect structure 213 includes a capacitor structure 284, and the front-side interconnect structure 216 includes a capacitor structure 255. The capacitor structures 402, 284 and 255 may serve as decoupling capacitors of the first semiconductor die 202 or the second semiconductor die 204, or both, and configured to filter noise of the power signal and stabilize the voltage of the power signal.

FIG. 2B is an enlarged view of a region A1 of the semiconductor die package 200 shown in FIG. 2A, in accordance with some embodiments of the present disclosure. The region A1 includes a portion of the backside interconnect structure 213 including the capacitor 284 (also applicable to the capacitor 402 or 255), conductive lines 278 and 282, and conductive vias 280A and 280B. The conductive lines 278 and 282 are formed in adjacent metal line layers Mn and M(n+1). That means the capacitor 284 is formed in the space of a metal via layer Vn between two adjacent metal line layers Mn and M(n+1), in which the capacitor 284 is electrically connected to the conductive lines 278 and 282 through conductive vias 280A and 280B, respectively. Referring to FIG. 2A and FIG. 2B, in the locations between the adjacent metal line layers Mn and M(n+1) where no capacitors are formed, the conductive via 280 extends to directly connect the metal lines in the metal line layers Mn and M(n+1). Two ends of the capacitor 284 (also applicable to capacitor 255 or 402), e.g., the upper surface of the first electrode 302 and the lower surface of the second electrode 304, are connected to the conductive vias 280A and 280B, respectively, in different directions, e.g., from the directions above and below the capacitor 284, respectively. According to other embodiments, the capacitor 284 occupy the space more than one metal via layer Vn, and the conductive vias 280A and 280B are electrically connected to non-adjacent metal line layers Mn and Mp, where p>n+1. According to some embodiments, referring to FIG. 2A, for the capacitor 402 or 255 formed around the bonding region 206, the first electrode 302 or the second electrode 304 on one end of the capacitor 402 or 255 is electrically connected to the conductive line, e.g., conductive line 234 or 256, through conductive vias 232 or 253, and is electrically connected to the conductive lines 404 directly on the other end of the capacitor 402 or 255.

Referring to FIG. 2B, the capacitor 284 is formed as an MIM capacitor, and includes a first electrode 302, a second electrode 304 and an insulating layer 306. According to some embodiments, the first electrode 302 and the second electrode 304 are physically and electrically connected to the conductive vias 280A and 280B, respectively. The first electrode 302 and the second electrode 304 are formed of conductive materials, such as elementary metal, refractory metal nitrides, conductive oxide, or the like. Example materials of the first electrode 302 and the second electrode 304 include tantalum (Ta), aluminum (Al), and copper (Cu), titanium nitride, tantalum nitride, indium oxide and molybdenum oxide. The first electrode 302 and the second electrode 304 may include the same or different materials. According to some embodiments, the first electrode 302 and the second electrode 304 have a thickness substantially equal to or greater than about 4 nm, e.g., in a range between about 4 and 20 nm.

According to some embodiments, the insulating layer 306 is arranged between the first electrode 302 and the second electrode 304. The insulating layer 306 may be or include a high-k material, such as ferroelectric oxide. Example materials of the insulating layer 306 include perovskite-structured materials, such as BaTiO₃ and PbZrO₂; fluorite-structured materials, such as HfO₂and ZrO₂; and wurtzite-structured nitrides, such as AlScN, AlBN and GaScN. According to some embodiments, the insulating layer 306 has a thickness substantially equal to or less than about 10 nm, e.g., in a range between about 2 and 10 nm.

According to some embodiments, the insulating layer 306 includes a dielectric material different from the dielectric material of the dielectric layer 236, 246 or 272. The insulating layer 306 may include a dielectric constant (k-value) greater than about 3.8. The insulating layer 306 may include a dielectric constant (k-value) greater than that of the dielectric layer 236, 246 and 272.

According to some embodiments, the capacitor structure 284, 402 and 255 further includes a first interfacial layer 308 arranged between the first electrode 302 and the insulating layer 306. Similarly, according to some embodiments, the capacitor structure 284, 402 and 255 further includes a second interfacial layer 310 arranged between the second electrode 304 and the insulating layer 306. The material of the first interfacial layer 308 or the second interfacial layer 310 may include titanium, tantalum, titanium nitride, tantalum nitride, or the like. The first interfacial layer 308 or the second interfacial layer 310 may be used to enhance the adhesion between the insulating layer 306 and the first electrode 302 or the second electrode 304. The first interfacial layer 308 or the second interfacial layer 310 may be used as a diffusion barrier layer to prevent diffusion of the conductive material in the first electrode 302 or the second electrode 304. The first interfacial layer 308 or the second interfacial layer 310 may further be used to reduce the breakdown failure of the insulating layer 306, also known as a time-dependent dielectric breakdown. According to some embodiments, the first interfacial layer 308 or the second interfacial layer 310 has a thickness less than or greater than that of the insulating layer 306. The number and functions of the layers of the capacitor 284 shown in FIG. 2B is provided for illustrative purposes. A capacitor configuration with other layer numbers equal to or greater than three is also within the contemplated scope of the present disclosure. According to some embodiments, a thickness of the capacitor 284 including the component layers, e.g., the first electrode 302, the second electrode 304, the insulating layer 306, the first interfacial layer 308 and the second interfacial layer 310, is less than about 400 Angstroms.

According to some embodiments, the capacitor 284, 255 or 402 is connected in parallel with the semiconductor devices 220 or 240 to achieve the purpose of protecting the semiconductor devices 220 or 240 from noise or disturbances. For example, the second electrode 304 of the capacitor 284 and the semiconductor device 220 are connected in parallel to the conductive line 282 of the backside interconnect structure 213.

According to some embodiments, the circuit density of the metal lines or metal vias is the greatest in the metal line layer M1 or the metal via layer V1 closest to the front side 211F or 215F and decreases along with the increase of the metal line layer Mn or the metal via layer Vn. Thus, in most cases, the circuit density of the metal lines or metal vias is the lowest in the metal line layer M_{N} or the metal via layer V_{N-1} farthest to the front side 211F or 215F, where the integer N denotes the layer number of the front-side interconnect structure 212, the backside interconnect structure 213 or the front-side interconnect structure 216. The front-side interconnect structure 212 or 216 may have the largest spare area for accommodation of the capacitors 284, 402 or 255 in the metal via layer V_{N-1} immediately adjacent to the bottommost or topmost metal line layer M_{N}. According to some embodiments, the capacitor 284, 402 and 255 are formed in a metal via layer V_{N-1} immediately adjacent to the topmost or bottommost metal line layer M_{N} (where the metal lines 234 or 252 resides) of the front-side interconnect structure 212, the backside interconnect structure 213 or the front-side interconnect structure 216 farthest to the respective front side 211F or 215F. The capacitor 402 is formed in the metal via layer where the conductive vias 232 or 253 resides, and is electrically connected to the overlying conductive line 256 or 404 or underlying conductive lines 234. Likewise, the capacitor 255 is formed in the metal via layer where the conductive vias 253 resides, and is electrically connected to the overlying or underlying conductive lines 252 through the conductive vias 253.

Although not separately shown, the semiconductor die package 200 may further include more capacitor structures in the substrate 223 or 243 to serve as the decoupling capacitors. The capacitor structure formed in the substrate 223 or 243 may be in a form of trench-type capacitor, e.g., deep-trench capacitors (DTC).

According to some embodiments, the first semiconductor die 202 is bonded with the second semiconductor die 204 at a bonding region 206 at an interface between the first semiconductor die 202 and the second semiconductor die 204. The conductive line 234 is arranged in the topmost metallization layer and connected to the conductive via 232 arranged in the topmost metal via layer, in which the conductive line 234 is used as a bonding pad in the bonding region 206. According to some embodiments, a bonding surface of the front-side interconnect structure 212 includes a metallic surface, e.g., a copper surface, which is generally provided by an upper surface of the conductive line 234, and a dielectric surface, e.g., an oxide surface, which is generally provided by an upper surface of a dielectric layer of the dielectric layer 236. Likewise, according to some embodiments, a bonding surface of the front-side interconnect structure 216 includes a metallic surface, e.g., a copper surface, which is generally provided by an upper surface of the conductive line 252, and a dielectric surface, e.g., an oxide surface, which is generally provided by an upper surface of a dielectric layer of the insulating layer 246. The bonding surfaces of the front-side interconnect structures 212 and 216 are bonded together to form hybrid bond, in which the metallic surfaces of the front-side interconnect structures 212 and 216 are bonded together while the dielectric surfaces of the front-side interconnect structures 212 and 216 are bonded together.

FIG. 2C is an enlarged view of the region A1 of the semiconductor die package 200 shown in FIG. 2A, in accordance with some embodiments of the present disclosure. FIG. 2C illustrates the capacitor 284, 402 or 253 in another form. For example, the capacitor 284, 402, 253 shown in FIG. 2C includes three layers, which include the first electrode 302, the second electrode 304 and the insulating layer 306. The materials and methods of forming for the first electrode 302, the second electrode 304, and the insulating layer 306 are similar to those described with reference to FIG. 2B in many aspects, and these similar features are not repeated for brevity.

According to some embodiments, the insulating layer 306 is in direct contact with the first electrode 302 and the second electrode 304. According to some embodiments, the widths or lengths of the first electrode 302, the second electrode 304, and the insulating layer 306 are substantially equal, and therefore the sidewalls of the first electrode 302, the second electrode 304, and the insulating layer 306 are aligned with each other. According to some embodiments, a thickness of the first electrode 302 or the second electrode 304 is greater than about 40 Angstroms. According to some embodiments, a thickness of the insulating layer 306 is less than about 100 Angstroms. According to some embodiments, a thickness sum of the first electrode 302, the second electrode 304 and the insulating layer 306 is less than about 400 Angstroms.

FIG. 2D is an enlarged view of the region A1 of the semiconductor die package 200 shown in FIG. 2A, in accordance with some embodiments of the present disclosure. FIG. 2C illustrates the capacitor 284, 402 or 253 in yet another form. For example, the capacitor 284, 402, 253 shown in FIG. 2D includes five layers, which include the first electrode 302, the second electrode 304, the insulating layer 306, the first interfacial layer 308 and the second interfacial layer 310, in manner similar to that shown in FIG. 2B. The materials and methods of forming for the first electrode 302, the second electrode 304, the insulating layer 306, the first interfacial layer 308 and the second interfacial layer 310 are similar to those described with reference to FIG. 2B in many aspects, and these similar features are not repeated for brevity.

According to some embodiments, the capacitor 284, 402 or 253 is formed in a recess of the dielectric layer 272. The recess may include a depth S1. As a result, each of the first electrode 302, the second electrode 304, the insulating layer 306, the first interfacial layer 308 and the second interfacial layer 310 has a curved or concave upward shape from a cross-sectional view.

According to some embodiments, the first electrode 302 or the first interfacial layer 308 have a width less than a width of the insulating layer 306, the second interfacial layer 310 or the second electrode 304. According to some embodiments, the capacitor 284, 402 or 253 further includes a mask layer 312 over the first electrode 302. The mask layer may be formed of a dielectric layer, such as silicon nitride, or another suitable mask material. The mask layer 312 may be used in patterning the first electrode 302 and the first interfacial layer 308. The conductive via 280A may extend to the first electrode 302 through the mask layer 312. According to some embodiments, through the patterning operation using the mask layer 312 as an etching mask, the sidewalls of the mask layer 312 are aligned with sidewalls of the first electrode 302 and the first interfacial layer 308.

According to some embodiments, the capacitor 284, 402 or 253 further includes spacers 314 on two sides of the first electrode 302 or the first interfacial layer 308. The spacers 314 may be formed of a dielectric layer, such as silicon nitride, silicon oxide, or another suitable dielectric material. The spacers 314 may be used in patterning the insulating layer 306, the second interfacial layer 310 and the second electrode 304. According to some embodiments, through the patterning operation using the spacers 314 as an etching mask, the outer sidewalls of the spacers 314 are aligned with sidewalls of the insulating layer 306, the second interfacial layer 310 and the second electrode 304.

FIG. 2E is a cross-sectional view of a semiconductor die package 201, in accordance with some embodiments of the present disclosure. The semiconductor die package 201 is similar to the semiconductor die package 200 in many aspects, and these similar features are not repeated for brevity. The semiconductor die package 201 is different from the semiconductor die package 200 mainly in that, in the semiconductor die package 201, the backside interconnect structure 213 includes only one metal via layer V0 including conductive vias 280 directly connected to the BTSVs 266, 268 and 270, and only one metal line layer M1 including conductive lines 282 (i.e., the metal line layers for the conductive lines 278 and 281 are removed from the backside interconnect structure 213), in which the capacitor 284 is formed in the metal via layer V0 between the BTSV 268 and the conductive via 280B.

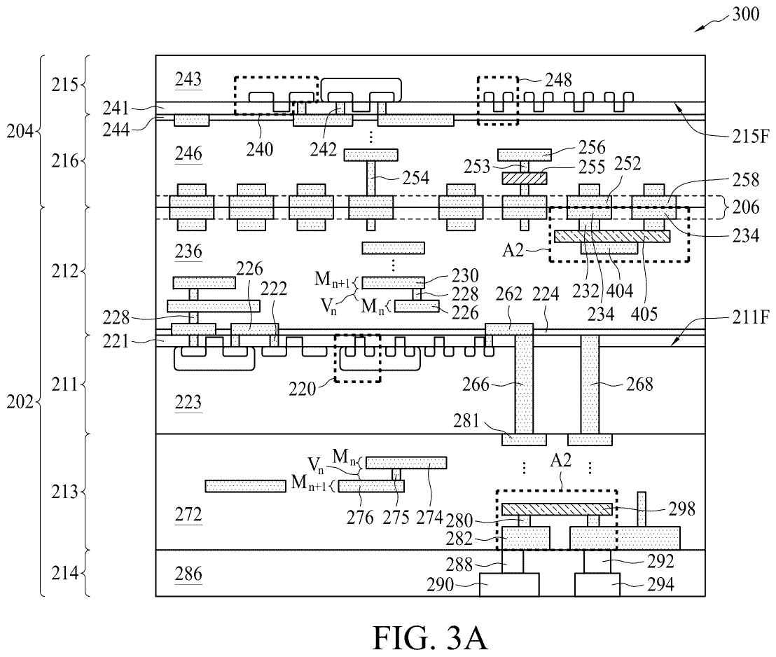

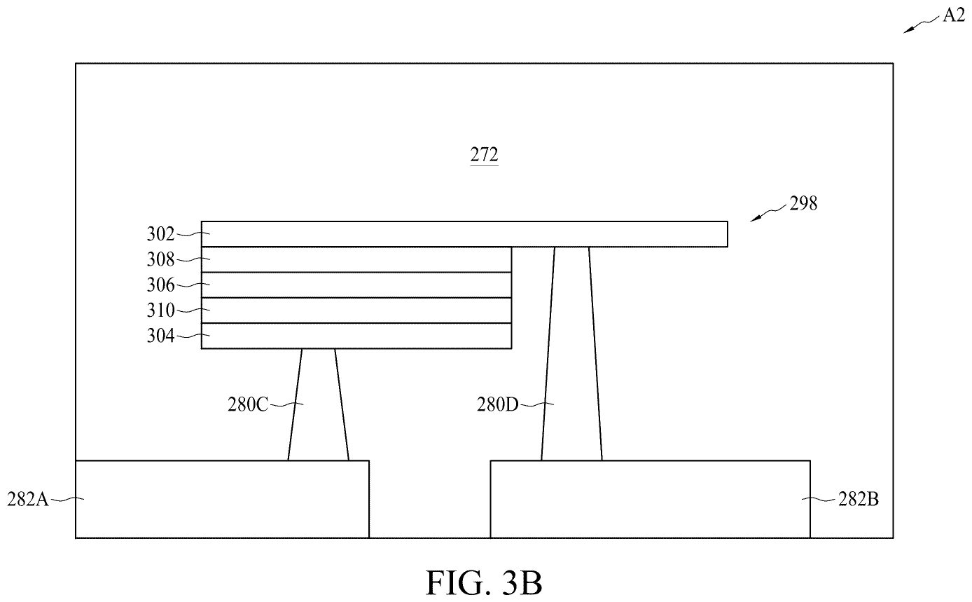

FIG. 3A is a cross-sectional view of a semiconductor die package 300, in accordance with some embodiments of the present disclosure. The semiconductor die package 300 is similar to the semiconductor die package 200 in many aspects, and details of these similar features are not repeated for brevity. The semiconductor die package 300 may be different from the semiconductor die package 200 in that the backside interconnect structure 213 of the semiconductor die package 300 includes a capacitor 298 electrically connected to the semiconductor devices 220 through the backside interconnect structure 213, the BTSVs 266, 268 and the front-side interconnect structure 216. Further, the front-side interconnect structure 212 of the semiconductor die package 300 includes a capacitor 406. The major difference between the capacitors 298, 406 and the capacitor 284 lies in that the capacitor 298 or 406 are connected to the conductive vias 280 or 234 from the same directions, e.g., from the direction below the capacitor 298 or over the capacitor 406.

FIG. 3B is an enlarged view of a region A2 of the semiconductor die package 300 shown in FIG. 3A, in accordance with some embodiments of the present disclosure. FIG. 3B shows the capacitor 298, conductive vias 280C, 280D and conductive lines 282A and 282B. The first electrode 302 and the second electrode 304 are electrically connected to the conductive lines 282A and 282B through the conductive vias 280C and 280D, respectively, from the lower surfaces of the first electrode 302 and the second electrode 304. The connection configuration of the capacitor 284 or 298 shown in FIG. 2B or 3B can be formed in the front-side interconnect structures 212 and 216 and the backside interconnect structure 213 in any type of combinations depending on various design requirements.

Referring to FIG. 3A and FIG. 3B, taking the capacitor 298 as an example, the conductive vias 288 and 292 of the RDL 214 electrically connect the conductive lines 282A and 282B to the conductive pads 290 and 294, respectively. According to some embodiments, the conductive pads 290 and 294 are electrically connected to a power terminal and a ground terminal, respectively, or vice versa, of an external power source. Although not separately shown, the backside interconnect structure 213 includes additional conduction paths to connect the capacitor 298 and the semiconductor devices 220 of the device region 211 in parallel, e.g., through the conductive line 282A. According to some embodiments, a thickness of the capacitor 298 including the component layers, e.g., the first electrode 302, the second electrode 304, the insulating layer 306, the first interfacial layer 308 and the second interfacial layer 310, is less than about 400 Angstroms.

According to some embodiments, the backside interconnect structure 213 includes only one metal line layer V0 and only one metal via layer M1, wherein the capacitor 298 shown in FIG. 3B is formed in the only one metal via layer V0, and the first electrode 302 and the second electrode 304 of the capacitor 298 are electrically connected to the conductive lines 282B and 282A, respectively, of the only one metal line layer through the conductive vias 280D and 280C, respectively.

Although FIGS. 2A and 3A illustrates the first type of capacitors 284, 402, 255, or the second type of 298 and 406 in only one semiconductor die package 200 or 300, these two types of capacitors 284, 402, 255, 298 and 406 can be used in a mixed manner in the semiconductor die package 200 or 300. In other words, different types of the capacitors 284, 402, 255, 298 and 406 can appear at the same time in different locations in a same semiconductor die package 200 or 300.

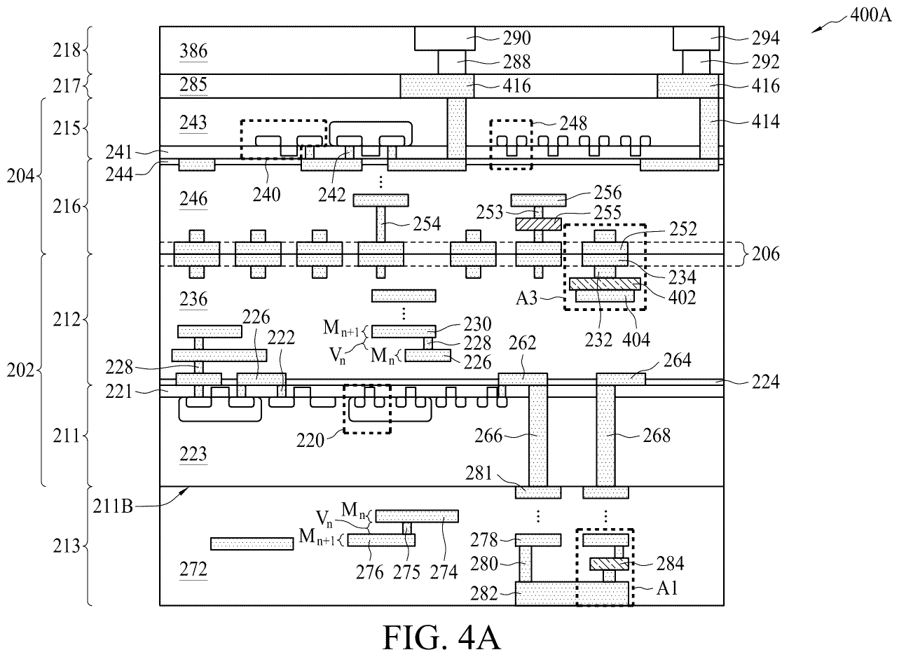

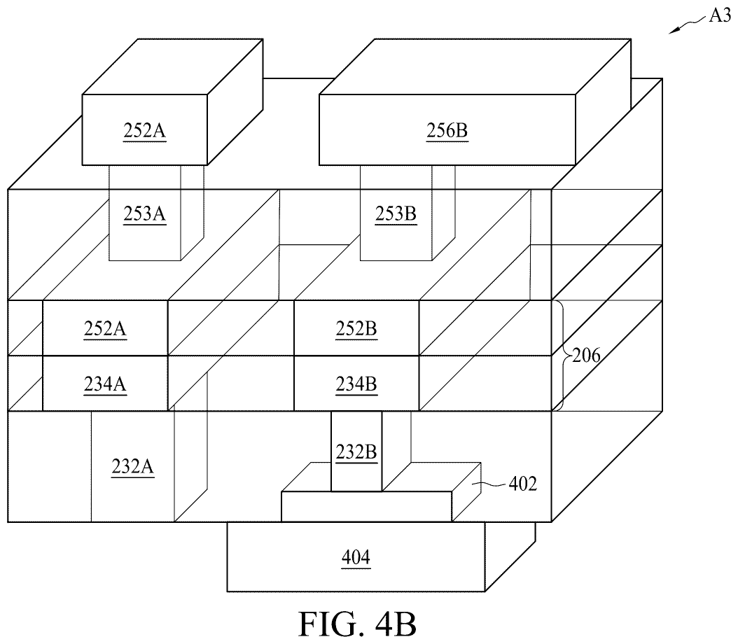

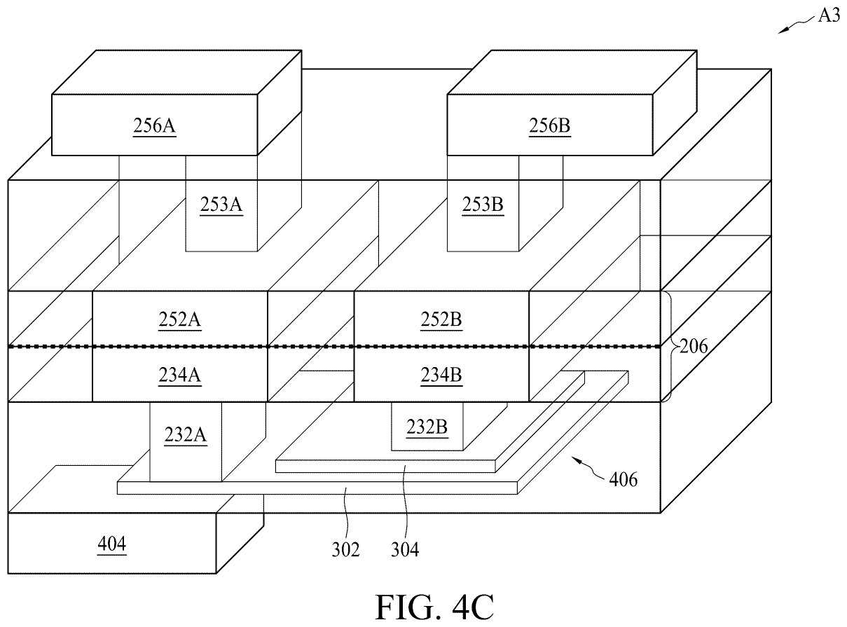

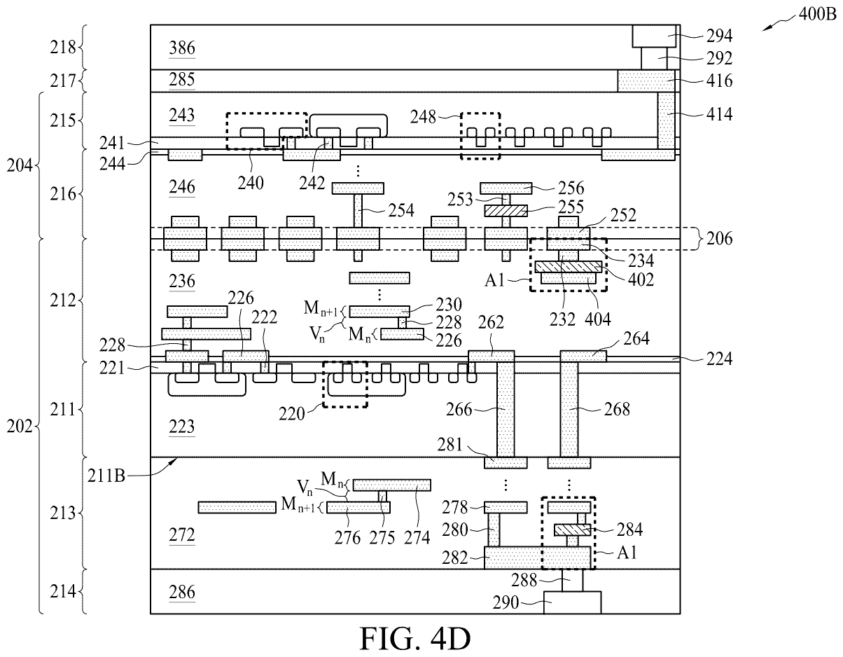

FIG. 4A is a cross-sectional view of a semiconductor die package 400A, in accordance with some embodiments of the present disclosure. The semiconductor die package 400A is similar to the semiconductor die package 200 in many aspects, and details of these similar features are not repeated for brevity. The semiconductor die package 400A may be different from the semiconductor die package 200 in that the second semiconductor die 204 of the semiconductor die package 400A includes a backside interconnect structure 217 and an RDL 218 in place of the RDL 214 of the first semiconductor die 202. According to some embodiments, the backside interconnect structure 217 includes a metallization layer, e.g., a metal line layer including a dielectric layer 285 and conductive lines 416. The dielectric layer 285 is similar to the dielectric layer 236, 246 and 272, and the conductive lines 416 is similar to the conductive lines of the front-side interconnect structures 212, 216 or the backside interconnect structure 213. According to some embodiments, the RDL 218 includes the conductive vias 288 and 292 and conductive pads 290 and 294 electrically connected to the conductive vias 288 and 292, respectively. The RDL 218 further includes a dielectric layer 386 electrically insulating the conductive vias 288 and 292 and conductive pads 290 and 294 in a manner similar to the dielectric layer 286. The conductive lines 416 are electrically connected to the conductive pads 290 and 294 through the conductive vias 288 and 292, respectively. The conductive pads 290 and 294 are electrically connected to a power terminal and a ground terminal, respectively, or vice versa, of an external power source to supply power and ground to the semiconductor die package 400A.

FIG. 4B is a perspective view of a region A3 of the semiconductor die package shown in FIG. 4A, in accordance with some embodiments of the present disclosure. According to some embodiments, the capacitor 402 is arranged in the front-side interconnect structure 212 of the first semiconductor die 202 and electrically connected to the conductive line 404 and the conductive vias 232B on two ends, e.g., the first electrode 302 and the second electrode 304, respectively, or vice versa. According to some embodiments, the conductive line 404 and the conductive via 232B are electrically connected to the representative conductive lines 256A and 256B, respectively, or vice versa, in the front-side interconnect structure 216 of the second semiconductor die 204, and the conductive lines 256A and 256B are electrically connected to the conductive pads 290 and 294 shown in FIG. 4A for connection with power and ground, respectively, of the power supply on the backside of the second semiconductor die 204.

FIG. 4C is a perspective view of the region A3 of the semiconductor die package shown in FIG. 4A, in accordance with some embodiments of the present disclosure. The perspective view shown in FIG. 4C is different from that shown in FIG. 4B in that the capacitor 202 shown in FIG. 4B is replaced with the capacitor 406 shown in FIG. 3A or 3B. According to some embodiments, the capacitor 406 is arranged in the front-side interconnect structure 212 of the first semiconductor die 202 and electrically connected to the conductive vias 232A and 232B on two ends, e.g., the first electrode 302 and the second electrode 304, respectively. According to some embodiments, the conductive vias 232A and 232B are electrically connected to the representative conductive lines 256A and 256B, respectively, or vice versa, in the front-side interconnect structure 216 of the second semiconductor die 204, and the conductive lines 256A and 256B are electrically connected to the conductive pads 290 and 294 shown in FIG. 4A for connection with power and ground, respectively, of the power supply on the backside of the second semiconductor die 204.

FIG. 4D is a cross-sectional view of a semiconductor die package 400B, in accordance with some embodiments of the present disclosure. The semiconductor die package 400B is similar to the semiconductor die package 200 or 400A in many aspects, and details of these similar features are not repeated for brevity. The semiconductor die package 400B may be different from the semiconductor die package 200 or 400A in that the conductive vias 288 and 292 are arranged in the RDLs 214 and 218, respectively, and the conductive pads 290 and 294 are arranged in the RDLs 214 and 218, respectively. The different configurations of the semiconductor die packages 200, 400A and 400B can be used in different applications depending on various design requirements.

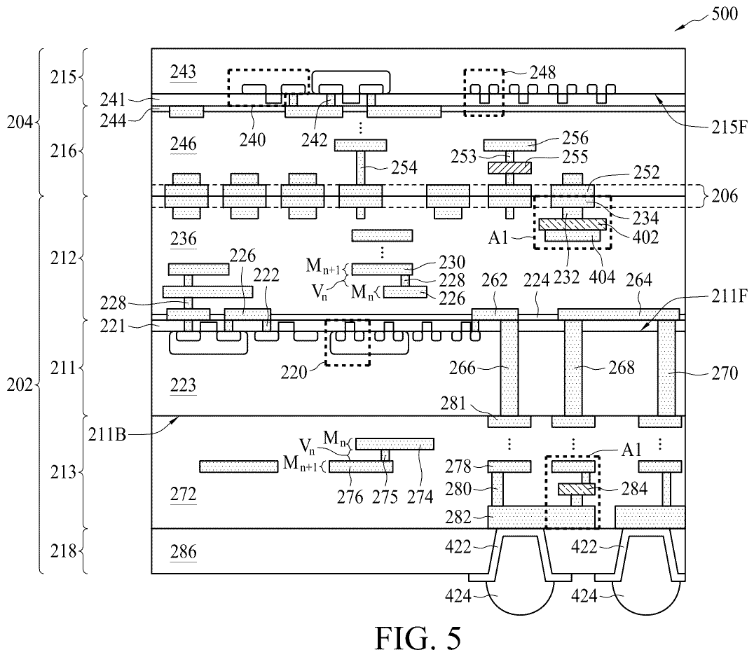

FIG. 5 is a cross-sectional view of a semiconductor die package 500, in accordance with some embodiments of the present disclosure. The semiconductor die package 500 is similar to the semiconductor die package 200 in many aspects, and details of these similar features are not repeated for brevity. The semiconductor die package 500may be different from the semiconductor die package 200 in that the conductive vias 288 and 292 and the conductive pads 290 and 294 are replaced with under-bump metallization (UBM) layers 422 and conductive bumps 424. According to some embodiments, the UBM layers 422 UBM are included in recesses of the dielectric layer 286. The UBM layers 422 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive material.

According to some embodiments, the conductive bumps 424 are electrically connected and/or physically connected to the UBM layers 422. The UBM layers 422 may facilitate adhesion to the metallization layers in the backside interconnect structure 213, and/or to enhance structural robustness of the conductive bumps 424. The conductive bumps 424 may form a ball grid array (BGA), a land grid array (LGA), a pin grid array (PGA), and/or another type of connectors. According to some embodiments, the conductive bumps 424 enable the semiconductor die package 500 to be mounted to a circuit board, a socket (e.g., an LGA socket), an interposer or redistribution structure of a semiconductor device package, and/or another type of mounting structure.

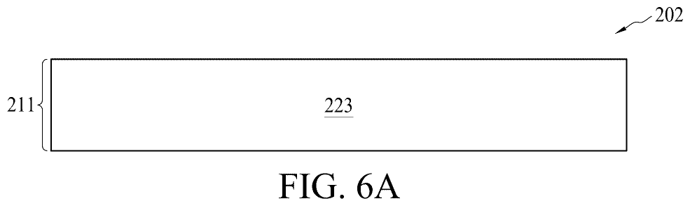

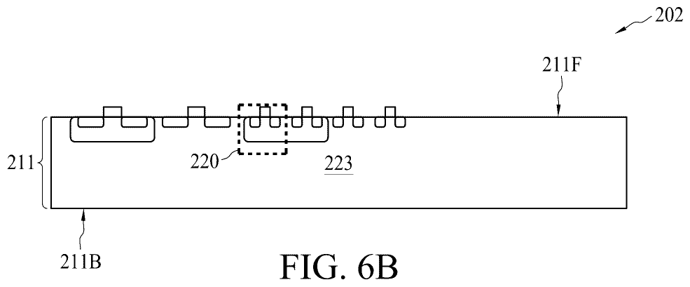

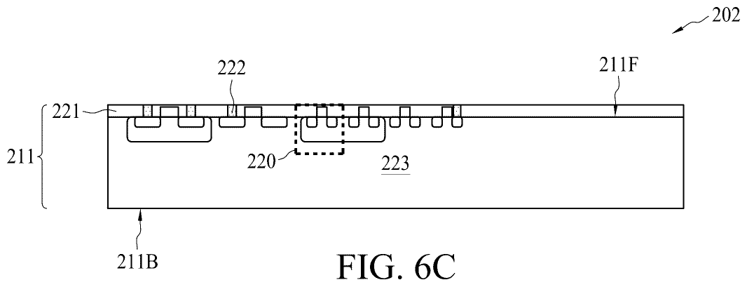

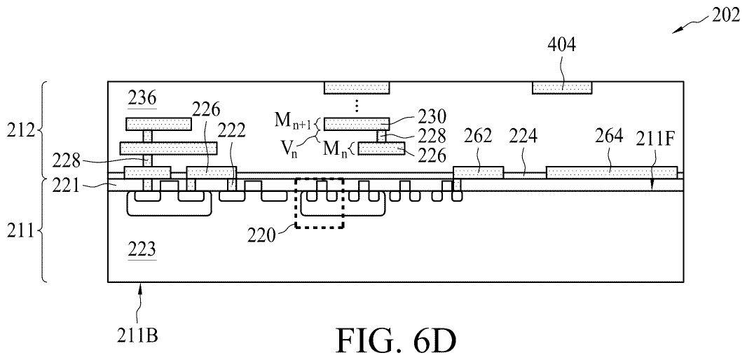

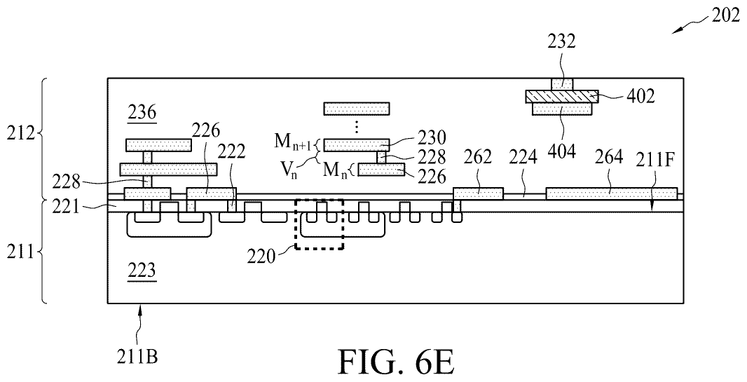

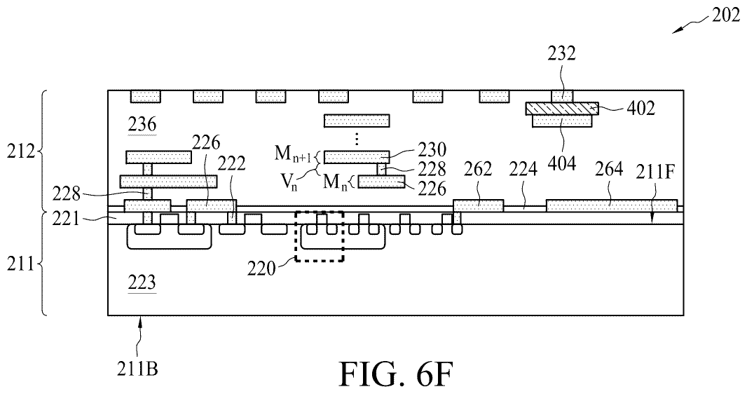

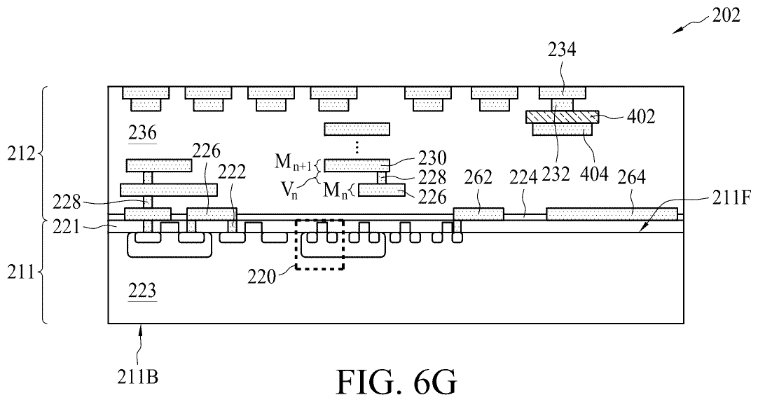

FIGS. 6A to 6G are schematic cross-sectional views of intermediate stages of a method of forming the first semiconductor die 202, in accordance with some embodiments of the present disclosure. Additional steps can be provided before, during, and after the steps of FIGS. 6A to 6G, and some of the steps described below can be replaced or eliminated in other embodiments. The order of the steps may be interchangeable. The steps for forming the first semiconductor die 202 can be performed using the tools 102-114 described with reference to FIG. 1.

Referring to FIG. 6A, a semiconductor substrate 223 for a device region 211 is provided or formed. Referring to FIG. 6B, one or more semiconductor devices 220 are formed on the front side 211F of the device region 211.

Referring to FIG. 6C, an ILD layer 221 is deposited over the front side 211F of the device region 211. According to some embodiments, one or more contacts 222 are formed in the ILD layer 221 to electrically connect the semiconductor devices 220.

FIGS. 6D to 6G shows a formation of the front-side interconnect structure 216. According to some embodiments, the metallization layers are formed one over another. FIG. 6D illustrates a portion of the front-side interconnect structure 216 is formed that includes a plurality of metal line layers and a plurality of metal via layers arranged alternatingly. An upper metal line layer with a plurality of conductive lines 404 is formed. The formation of the conductive lines and/or conductive vias may be performed using single damascene or dual damascene processes.

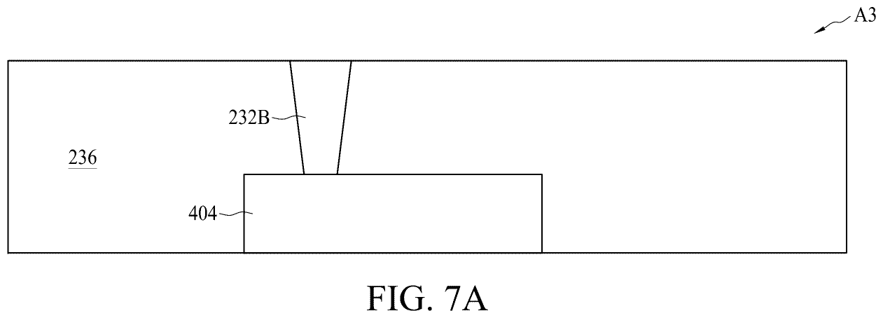

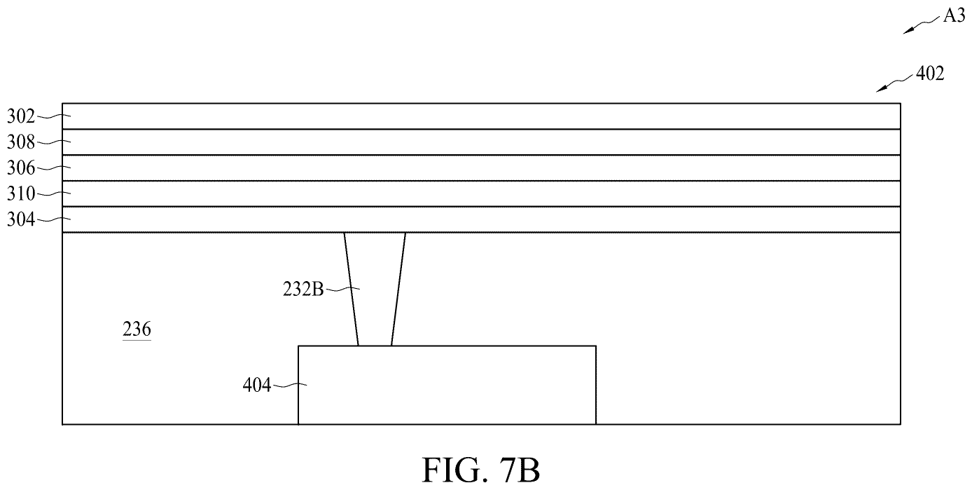

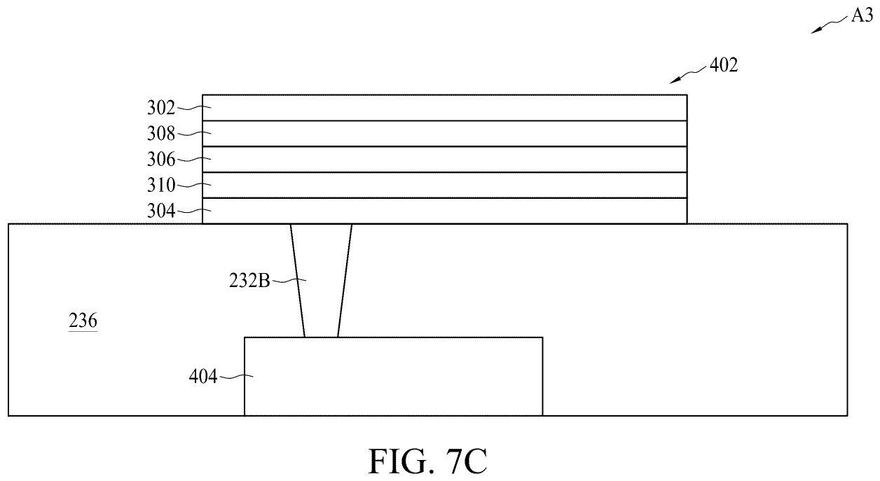

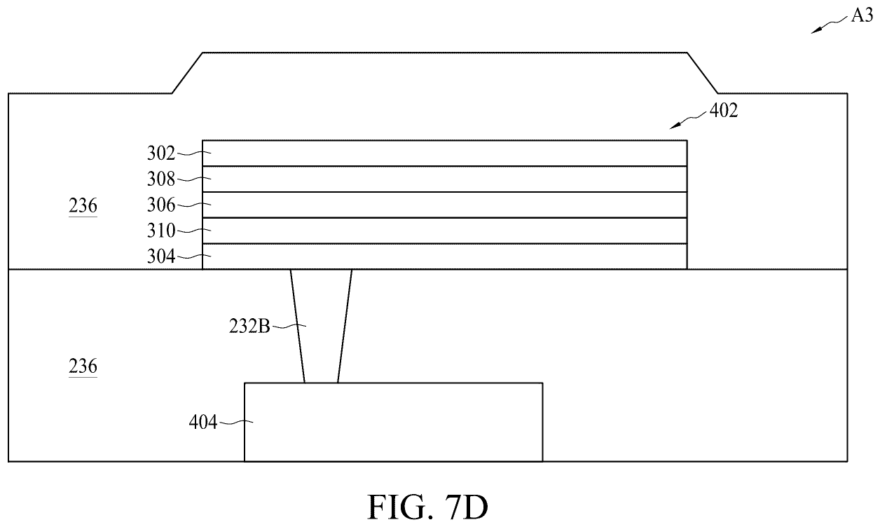

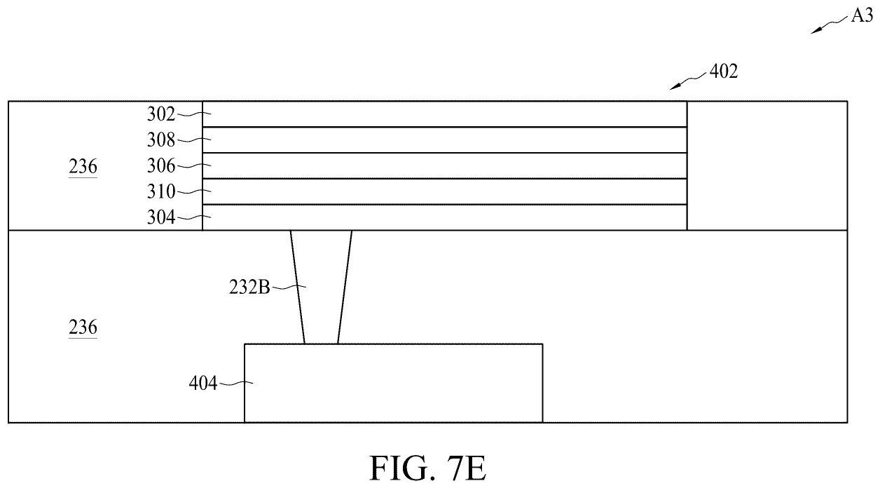

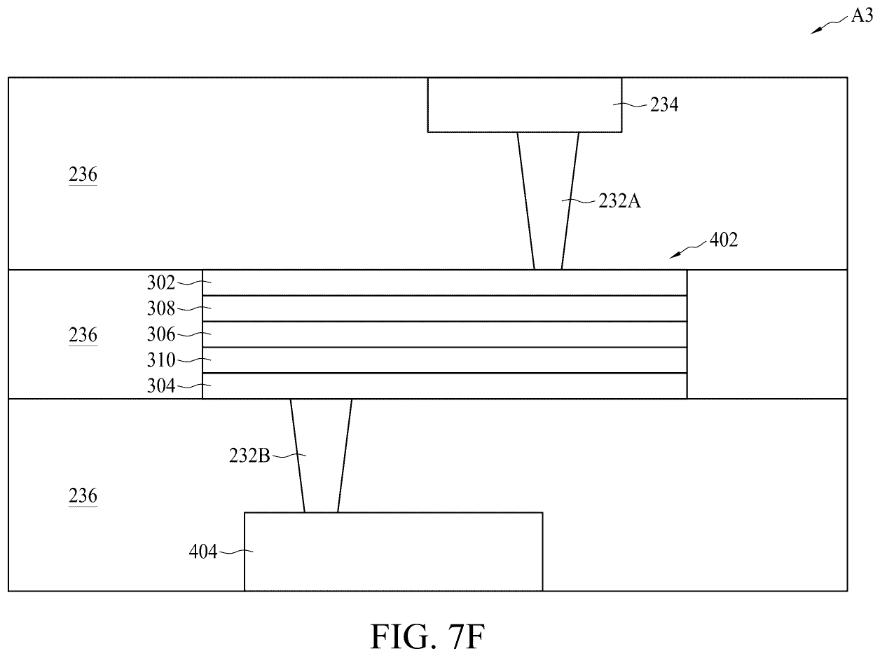

Subsequently, as shown in FIG. 6E, the conductive via 232 and the capacitor 402 are subsequently formed over one of the conductive line 404. FIGS. 7A to 7F are schematic cross-sectional views of intermediate stages of a method of forming the capacitor 402 and its surrounding structures, in accordance with some embodiments of the present disclosure. The formation method of the capacitor 402 described with reference to FIGS. 7A to 7F is also applicable to that of the capacitor 284 or 235, wherein some modifications known to the persons of ordinary skill in the art may be employed. Additional steps can be provided before, during, and after the steps of FIGS. 7A to 7F, and some of the steps described below can be replaced or eliminated in other embodiments. The order of the steps may be interchangeable. The steps for forming the capacitor 402 can be performed using the tools 102-114 described with reference to FIG. 1.

Referring to FIG. 7A, the dielectric layer 236 has been formed. The conductive line 404 is deposited in a recess of the dielectric layer 236. According to some embodiments, a material of the dielectric layer 236 is subsequently deposited over the original dielectric layer 236 and the conductive line 404. A recess is etched in the dielectric layer 236 over the conductive line 404 and exposes an upper surface of the conductive line 404. A conductive material is deposited in the recess and fills the recess. According to some embodiments, a planarization operation is performed to remove excess materials of the conductive material and level the conductive material with the upper surface of the dielectric layer 236, thereby forming the conductive via 232B.

Referring to FIG. 7B, materials of a stack of the capacitor 402 are deposited. For example, material layers of the second electrode 304, the second interfacial layer 310, the insulating layer 306, the first interfacial layer 308 and the first electrode 302 are successively deposited over the dielectric layer 236 and the conductive via 232B.

FIG. 7C shows a patterning operation performed on the stack of the capacitor 402 to generate a desired pattern of the capacitor 402. The patterning operation may include photolithography and etching operations. The etching operation may include a wet etch, a dry etch, an RIE, or the like.

Subsequently, a material layer of the dielectric layer 236 is deposited over the layer stack of the capacitor 402, as illustrated in FIG. 7D. FIG. 7E shows a planarization operation on the dielectric layer 236 to remove excess materials of the dielectric layer 236 over the layer stack of the capacitor 402 and level the upper surface of the first electrode 302 with the upper surface of the dielectric layer 236.

Referring to FIG. 7F, an additional layer of the dielectric layer 236 is formed. The conductive line 234 is deposited in a recess of the dielectric layer 236. According to some embodiments, a material of the dielectric layer 236 is subsequently deposited over the original dielectric layer 236 and the conductive line 404. A recess is etched in the dielectric layer 236 over the first electrode 302 and exposes an upper surface of the first electrode 302. The recess may include a via recess and a line recess over one another. A conductive material is deposited in the via recess and the line recess. According to some embodiments, a planarization operation is performed to remove excess materials of the conductive material and level the conductive material with the upper surface of the dielectric layer 236, thereby forming the conductive line 234 and the conductive via 232A. As shown in FIG. 6E and FIG. 7F, the capacitor 402 is formed in a metal via layer V_{N-1} adjacent to the topmost metal line layer V_{N}.

Referring to FIG. 6F, the conductive vias 232 of the metal via layer V_{N-1} are formed adjacent to the capacitor 402. The method of forming for the conductive vias 232 free of the capacitor 402 is similar to that of forming the conductive vias 232A and 232B connected to the capacitor 402.

Referring to FIG. 6G, the topmost metal line layer M_{N} is formed on the front-side interconnect structure 212. The topmost metal line layer M_{N} includes a plurality of conductive lines 234, serving as bonding pads of the bonding region 206 of a hybrid bond.

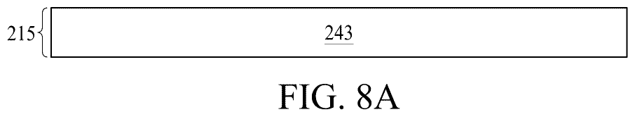

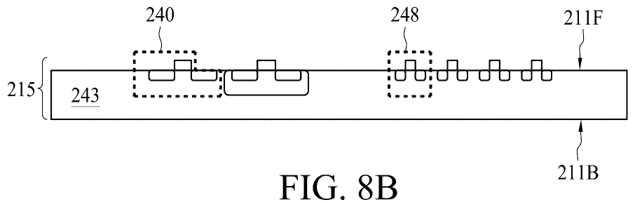

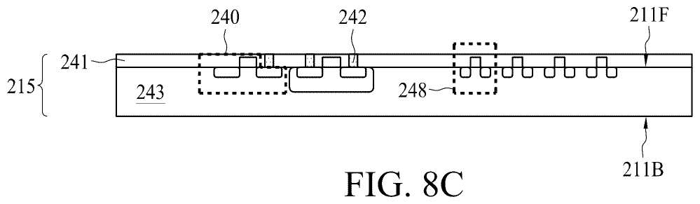

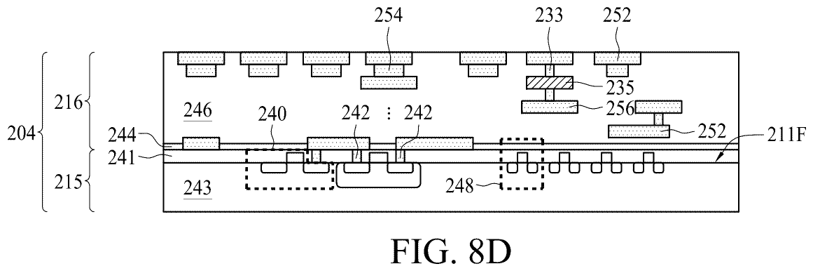

FIGS. 8A to 8D are schematic cross-sectional views of intermediate stages of a method of forming the semiconductor die 204, in accordance with some embodiments of the present disclosure. Additional steps can be provided before, during, and after the steps of FIGS. 8A to 8D, and some of the steps described below can be replaced or eliminated in other embodiments. The order of the steps may be interchangeable. The steps for forming the second semiconductor die 204 can be performed using the tools 102-114 described with reference to FIG. 1.

Referring to FIG. 8A, a semiconductor substrate 243 for a device region 215 is provided or formed. Referring to FIG. 8B, one or more semiconductor devices 240 are formed on the front side 215F of the device region 215. According to some embodiments, one or more semiconductor devices 248 are also formed on the front side 215F, in which the semiconductor devices 240 and 248 may include active devices and passive devices, respectively.

Referring to FIG. 8C, an ILD layer 241 is deposited over the front side 215F of the device region 215. According to some embodiments, one or more contacts 242 are formed in the ILD layer 241 to electrically connect the semiconductor devices 240 or 248.

FIG. 8D shows a formation of the front-side interconnect structure 216. According to some embodiments, the metallization layers are formed one over another. FIG. 8D illustrates that a plurality of metal line layers and a plurality of metal via layers are formed alternatingly. Moreover, a capacitor 235 is also formed in the metal via layer V_{N-1} and electrically connected to the other conductive lines 252 through the conductive vias 233. The formation of the conductive lines 252 and/or conductive vias 233, 254 may be performed using single damascene or dual damascene processes. The topmost metal line layer M_{N} is formed on upper surface of the front-side interconnect structure 216. The topmost metal line layer M_{N} includes a plurality of conductive lines 252, serving as bonding pads of the bonding region 206 of a hybrid bond.

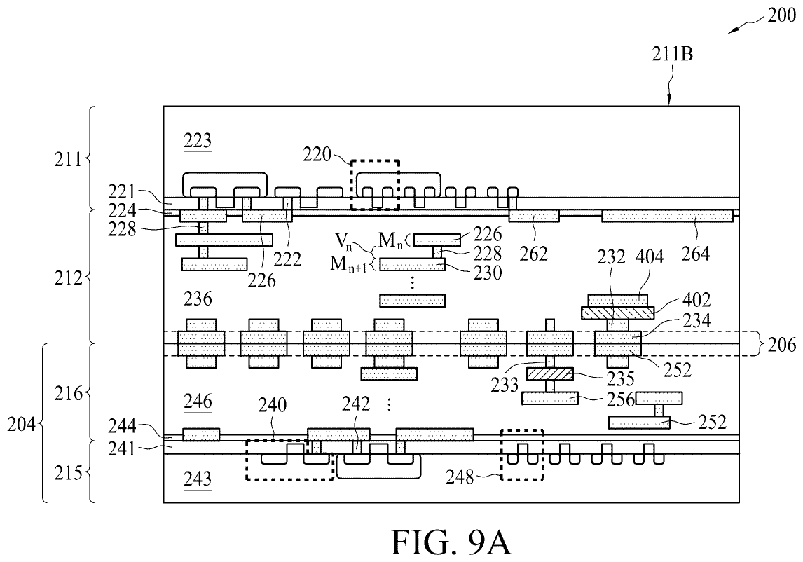

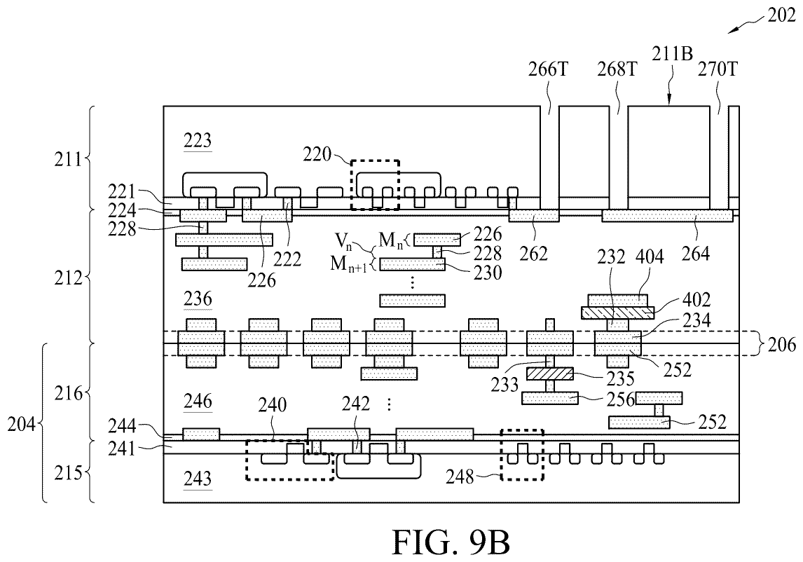

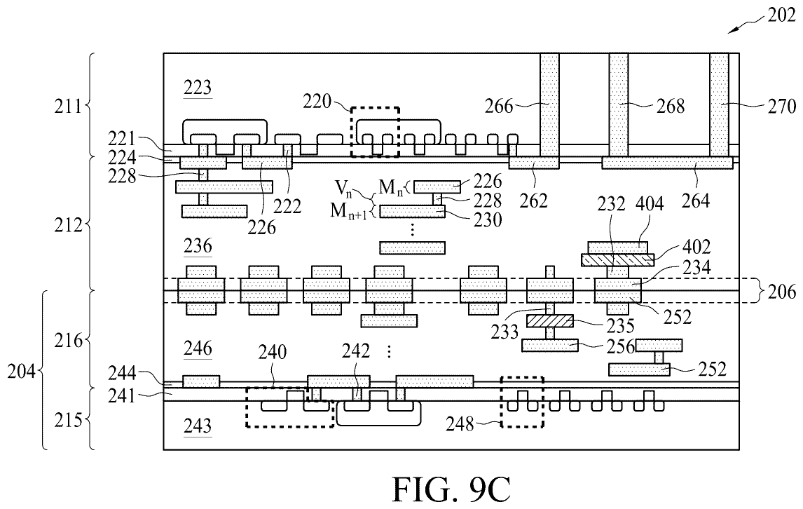

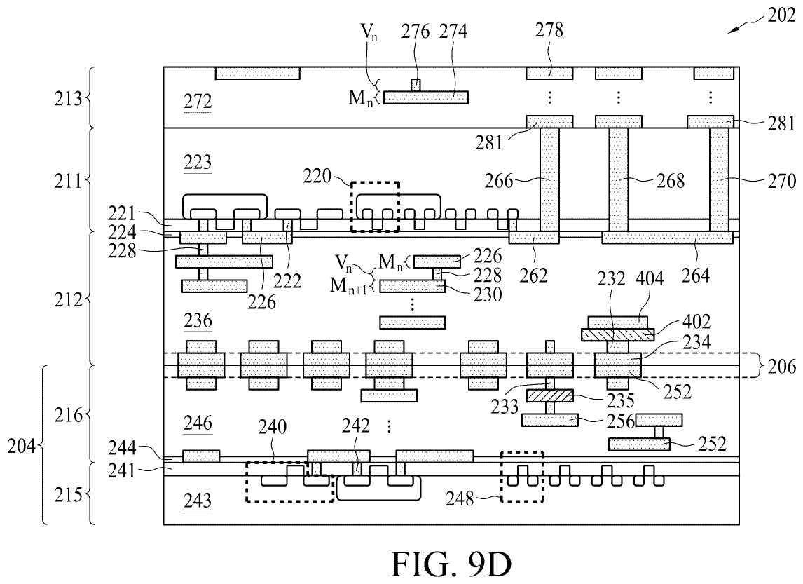

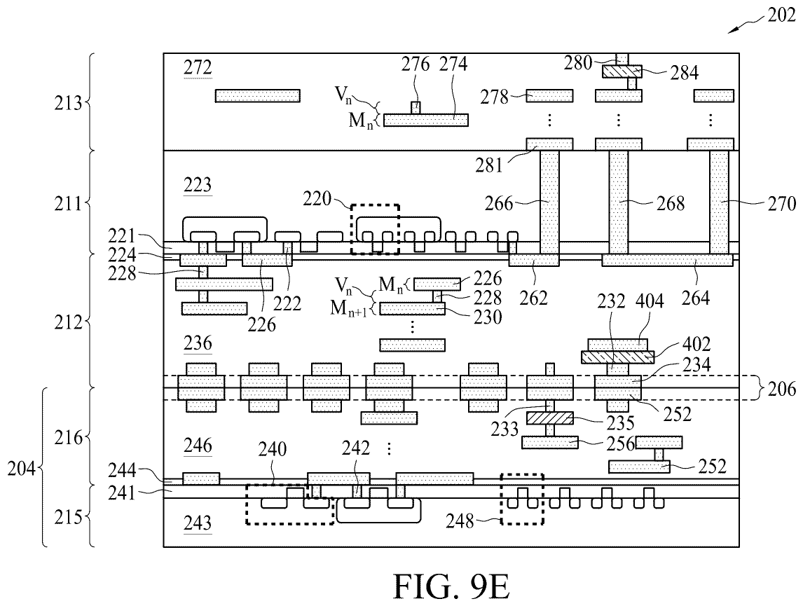

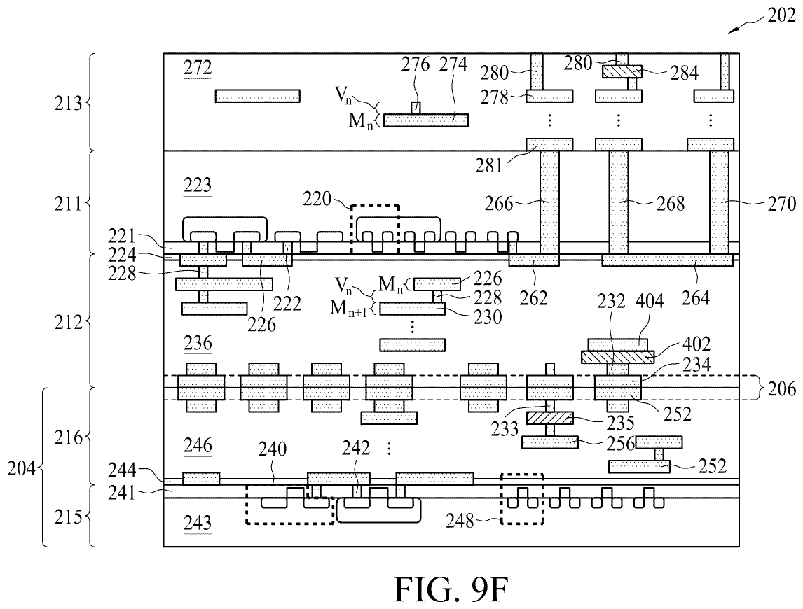

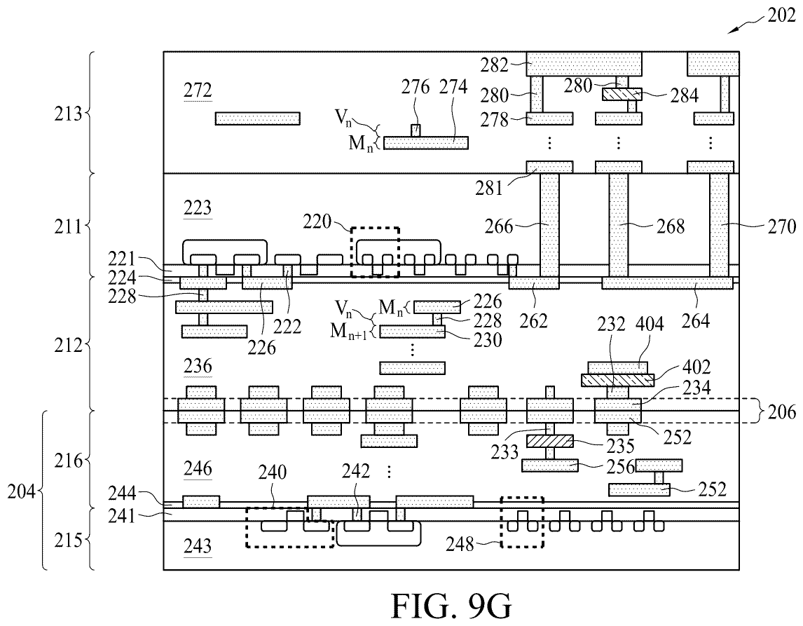

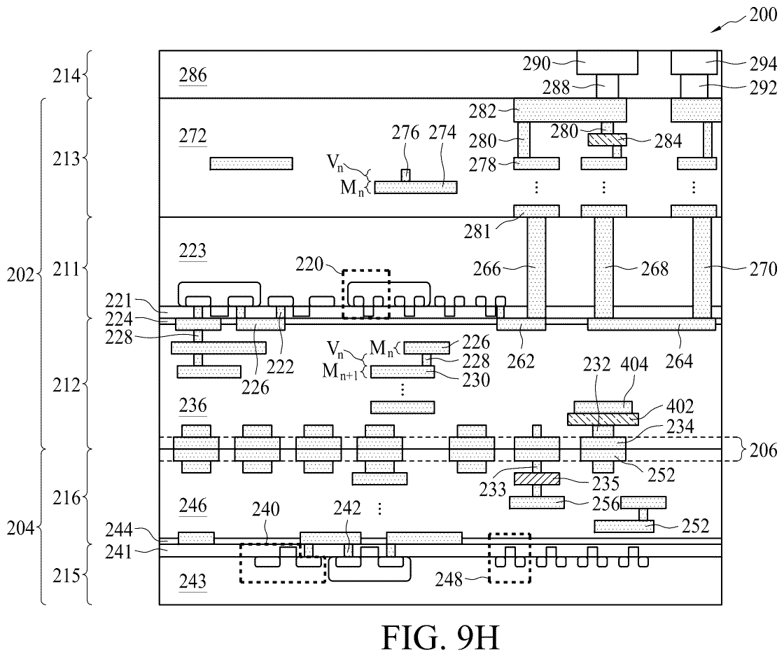

FIGS. 9A to 9H are schematic cross-sectional views of intermediate stages of a method of forming the semiconductor die package 200, in accordance with some embodiments of the present disclosure. Additional steps can be provided before, during, and after the steps of FIGS. 9A to 9H, and some of the steps described below can be replaced or eliminated in other embodiments. The order of the steps may be interchangeable. The steps for forming the semiconductor die package 200 can be performed using the tools 102-114 described with reference to FIG. 1.

Referring to FIG. 9A, one of the first semiconductor die 202 and the second semiconductor die 204 is flipped such that the backside 211B is caused to face upward, and the first semiconductor die 202 and the second semiconductor die 204 are bonded together at the bonding region 206. As discussed previously, the conductive lines 234 and 252 of the front-side interconnect structures 212 and 216 provide the metallic bonding surfaces, while the dielectric layers 236 and 246 of the front-side interconnect structures 212 and 216 provide the dielectric (e.g., oxide) bonding surfaces. A hybrid bond is formed, in which the metallic bonding surfaces are bonded together to form metallic bonds, and the dielectric bonding surfaces are bonded together to form dielectric bonds. According to some embodiments, the bonding tool 112 is configured to perform the hybrid bonding operation to support auxiliary functions of the hybrid bonding operation, e.g., die alignment, initial bonding, complete bonding, thermal/compression bonding, or the like.

Referring to FIG. 9B, an etching operation is performed to form through vias 266T, 268T and 270T through the thickness of the semiconductor substrate 223. The etching operation may include laser etch, dry etch, RIE, or the like.

FIG. 9C shows the formation of the BTSVs 266, 268 and 270 in the through vias 266T, 268T and 270T, respectively. A conductive material is deposited in the through vias 266T, 268T and 270T. According to some embodiments, a planarization operation is performed to level the upper surface of the through vias 266T, 268T and 270T with the backside 211B.

FIGS. 9D to 9G shows a formation of the backside interconnect structure 213. The method of forming the backside interconnect structure 213 is similar to that of forming the front-side interconnect structure 212 or 216 described previously with reference to FIGS. 6D to 6G or FIG. 8D, and these similar features are not repeated for brevity. Moreover, as shown in FIG. 9E, the conductive via 280 and the capacitor 284 are formed in a metal via layer V_{N-1} immediately adjacent to the topmost metal line layer M_{N}. The formation of the capacitor 284 is shown in the descriptions with reference to FIGS. 7A to 7F.

Referring to FIG. 9H, the RDL 214 is formed over the backside interconnect structure 213. A dielectric layer 286 is deposited over the backside interconnect structure 213. Subsequently, recesses are formed in the dielectric layer 286, followed by a deposition operation of a conductive material on the recesses to form the conductive vias 288 and 292 electrically connected to the backside interconnect structure 213. The similar procedure described above is repeated to form the conductive pads 290 and 294 to be electrically connected to the conductive vias 288 and 292, respectively.

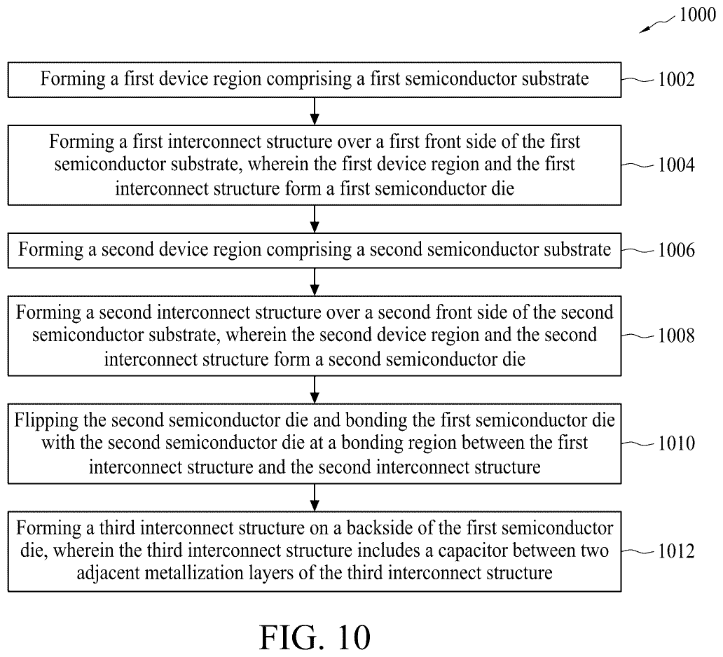

FIG. 10 shows a flowchart of a method 1000 of manufacturing a semiconductor waveguide device, in accordance with some embodiments of the present disclosure. It should be understood that additional steps can be provided before, during, and after the steps in the method 1000, and some of the steps described below can be replaced with other embodiments or eliminated altogether. An order of the steps shown in FIG. 10 may be interchangeable. Some of the steps may be performed concurrently or independently.

In step 1002, a first device region comprising a first semiconductor substrate is formed.

In step 1004, a first interconnect structure is formed over a first front side of the first semiconductor substrate, wherein the first device region and the first interconnect structure form a first semiconductor die.

In step 1006, a second device region comprising a second semiconductor substrate is formed.

In step 1008, a second interconnect structure is formed over a second front side of the second semiconductor substrate, wherein the second device region and the second interconnect structure form a second semiconductor die.

In step 1010, the second semiconductor die is flipped and the first semiconductor die is bonded with the second semiconductor die at a bonding region between the first interconnect structure and the second interconnect structure.

In step 1012, a third interconnect structure is formed on a backside of the first semiconductor die, wherein the third interconnect structure includes a capacitor between two adjacent metallization layers of the third interconnect structure.

According to an embodiment, a method includes: forming a first device region including a first semiconductor substrate; forming a first interconnect structure over a first front side of the first semiconductor substrate, wherein the first device region and the first interconnect structure form a first semiconductor die; forming a second device region including a second semiconductor substrate; forming a second interconnect structure over a second front side of the second semiconductor substrate, wherein the second device region and the second interconnect structure form a second semiconductor die; flipping the second semiconductor die and bonding the first semiconductor die with the second semiconductor die at a bonding region between the first interconnect structure and the second interconnect structure; and forming a third interconnect structure on a backside of the first semiconductor substrate, wherein the third interconnect structure includes a capacitor between two adjacent metallization layers of the third interconnect structure.

According to an embodiment, a method includes: providing a first device region including a first semiconductor substrate; forming a first interconnect structure over a first front side of the first semiconductor substrate, wherein the first device region and the first interconnect structure form a first semiconductor die; providing a second device region including a second semiconductor substrate; forming a second interconnect structure over a second front side of the second semiconductor substrate, wherein the second device region and the second interconnect structure form a second semiconductor die, wherein each of the first interconnect structure and the second interconnect structure includes a plurality of metallization layers, and at least one of the first semiconductor substrate and the second semiconductor substrate includes a third interconnect structure on a backside thereof; forming a capacitor in at least one of the first interconnect structure, second interconnect structure and third interconnect structure in a location immediately adjacent to a topmost metallization layer of the plurality of metallization layers; and bonding the first semiconductor die with the second semiconductor die at a bonding region between the first interconnect structure and the second interconnect structure.

According to an embodiment, a semiconductor structure includes: a first semiconductor die including: a first device region on a first front side of a first semiconductor substrate; and a first interconnect structure over the first front side; and a second interconnect structure on a backside of the first semiconductor substrate. The semiconductor structure also includes a second semiconductor die bonded with the first semiconductor die at a bonding region between the first interconnect structure and a third interconnect structure of the second semiconductor die, the second semiconductor die including: a second device region on a second front side of a second semiconductor substrate; and the third interconnect structure over the second front side. The semiconductor structure further includes a capacitor arranged in at least one of the first interconnect structure, the second interconnect structure and the third interconnect structure in a location immediately adjacent to a topmost metallization layer of the first interconnect structure, the second interconnect structure or the third interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first device region comprising a first semiconductor substrate;
forming a first interconnect structure over a first front side of the first semiconductor substrate, wherein the first device region and the first interconnect structure form a first semiconductor die;
forming a second device region comprising a second semiconductor substrate;
forming a second interconnect structure over a second front side of the second semiconductor substrate, wherein the second device region and the second interconnect structure form a second semiconductor die;
flipping the second semiconductor die and bonding the first semiconductor die with the second semiconductor die at a bonding region between the first interconnect structure and the second interconnect structure; and
forming a third interconnect structure on a backside of the first semiconductor substrate, wherein the third interconnect structure comprises a capacitor between two adjacent metallization layers of the third interconnect structure.

2. The method according to claim 1, further comprising forming a first conductive via extending through the first semiconductor substrate and electrically connecting the first interconnect structure to the third interconnect structure.

3. The method according to claim 2, wherein the third interconnect structure comprises only one metal line layer and only one metal via layer, wherein the capacitor is formed in the only one metal via layer and comprises a first electrode and a second electrode electrically connected to the first conductive via and a conductive line in the only one metal line layer, respectively.

4. The method according to claim 3, further comprising forming a first conductive pad over the third interconnect structure and configured to provide power or ground to the first semiconductor die and the second semiconductor die, the first conductive pad electrically connected to the first electrode.

5. The method according to claim 4, further comprising:
forming a second conductive via extending through the first semiconductor substrate; and
forming a second conductive pad in a first redistribution layer over the third interconnect structure and electrically connected to the second conductive via,
wherein the second conductive pad is configured to provide power or ground to the first semiconductor die and the second semiconductor die, the second conductive pad electrically connected to the second electrode.

6. The method according to claim 4, further comprising forming a third conductive via extending through the first semiconductor substrate and electrically connected to the first conductive pad and the first electrode.

7. The method according to claim 2, wherein the third interconnect structure comprises only one metal via layer and only one metal line layer, wherein the capacitor is formed in the only one metal via layer and comprises two electrodes electrically connected to two respective conductive lines in the only one metal line layer.

8. The method according to claim 7, further comprising forming a first conductive pad and a second conductive pad in a second redistribution layer over the third interconnect structure, the first conductive pad and the second conductive pad configured to provide power and ground, respectively, to the first semiconductor die and the second semiconductor die, wherein the first conductive pad and the second conductive pad are electrically connected to the two electrodes, respectively.

9. The method according to claim 1, wherein each of the first interconnect structure, the second interconnect structure and the third interconnect structure comprises a dielectric layer, and the capacitor comprises an insulating layer between and electrically insulating two electrodes of the capacitor, wherein the insulating layer is different from the dielectric layer.

10. The method according to claim 9, wherein the insulating layer comprises ferroelectric oxide.

11. A method, comprising:
providing a first device region comprising a first semiconductor substrate;
forming a first interconnect structure over a first front side of the first semiconductor substrate, wherein the first device region and the first interconnect structure form a first semiconductor die;
providing a second device region comprising a second semiconductor substrate;
forming a second interconnect structure over a second front side of the second semiconductor substrate, wherein the second device region and the second interconnect structure form a second semiconductor die, wherein each of the first interconnect structure and the second interconnect structure comprises a plurality of metallization layers, and at least one of the first semiconductor substrate and the second semiconductor substrate comprises a third interconnect structure on a backside thereof;
forming a capacitor in at least one of the first interconnect structure, second interconnect structure and third interconnect structure in a location immediately adjacent to a topmost metallization layer of the plurality of metallization layers; and
bonding the first semiconductor die with the second semiconductor die at a bonding region between the first interconnect structure and the second interconnect structure.

12. The method according to claim 11, wherein the first semiconductor die is bonded to the second semiconductor die through hybrid bonding.

13. The method according to claim 11, wherein the capacitor comprises two electrodes facing the topmost metallization layer and electrically connected to two corresponding conductive lines in the topmost metallization layer.

14. The method according to claim 13, further comprising forming a first conductive pad and a second conductive pad in a redistribution layer over the second semiconductor die, the first conductive pad and the second conductive pad configured to provide power and ground, respectively, to the first semiconductor die and the second semiconductor die, wherein the first conductive pad and the second conductive pad are electrically connected to the two electrodes, respectively.

15. The method according to claim 11, wherein the capacitor is arranged in the third interconnect structure, comprising forming a conductive via extending through the first semiconductor substrate or the second semiconductor substrate and electrically connected to a first electrode of the capacitor.

16. The method according to claim 15, further comprising forming a second conductive via extending through the first semiconductor substrate and electrically connected to a second electrode of the capacitor through the first interconnect structure or the second interconnect structure.

17. The method according to claim 11, wherein the capacitor is electrically connected to a semiconductor device on the first semiconductor substrate or the second semiconductor substrate in parallel.

18. A semiconductor structure, comprising:
a first semiconductor die, comprising:
a first device region comprising a first semiconductor substrate; and
a first interconnect structure over a first front side of the first semiconductor substrate; and
a second interconnect structure on a backside of the first semiconductor substrate;
a second semiconductor die bonded with the first semiconductor die at a bonding region between the first interconnect structure and a third interconnect structure of the second semiconductor die, the second semiconductor die comprising:
a second device region comprising a second semiconductor substrate; and
the third interconnect structure over a second front side of the second semiconductor substrate; and
a capacitor arranged in at least one of the first interconnect structure, the second interconnect structure and the third interconnect structure in a location immediately adjacent to a topmost metallization layer of the first interconnect structure, the second interconnect structure or the third interconnect structure.

19. The semiconductor structure according to claim 18, wherein the capacitor is arranged in the second interconnect structure, further comprising a first conductive via and a second conductive via extending through the first semiconductor substrate and electrically connected to two electrodes of the capacitor.

20. The semiconductor structure according to claim 19, further comprising a redistribution layer arranged over the second interconnect structure and comprising a first conductive pad and a second conductive pad electrically connected to the two electrodes, respectively.
